(19) United States
(12) Patent Application Publication
(10) Pub. No.: US 2020/0373225 A1
(43) Pub. Date: Nov. 26, 2020

(54) SEMICONDUCTOR INTEGRATED CIRCUIT AND CIRCUIT LAYOUT METHOD THEREOF

(71) Applicant: WIN Semiconductors Corp., Tao Yuan City (TW)

(72) Inventors: Chih-Hsien CHANG, Tao Yuan City (TW); Wen CHU, Tao Yuan City (TW); Chang-Hwang HUA, Tao Yuan City (TW); Clement HUANG, Tao Yuan City (TW)

(21) Appl. No.: 16/658,557

(22) Filed: Oct. 21, 2019

(30) Foreign Application Priority Data
May 22, 2019 (TW) 108117734

(51) Int. Cl. H01L 23/48; H01L 21/768; H01L 23/64; H01L 23/00

(52) U.S. Cl. CPC H01L 23/481; H01L 21/76898; H01L 23/645; H01L 21/76874; H01L 2224/16227; H01L 24/16; H01L 2224/0401; H01L 2224/0557; H01L 2224/05009; H01L 24/05

(57) ABSTRACT

A semiconductor integrated circuit comprises a semiconductor substrate having a via-hole, a front-side-metal layer formed on a top surface of the semiconductor substrate, a seed-metal layer and a backside-metal layer. A bottom surface of an inner surface of the via-hole is at least partially defined by the front-side-metal layer. A surrounding surface of the inner surface of the via-hole is at least partially defined by the semiconductor substrate. The seed-metal layer is formed on the inner surface of the via-hole and a bottom surface of the semiconductor substrate such that the seed-metal layer and the front-side-metal layer are connected. The backside-metal layer is formed on an outer surface of the seed-metal layer. An aspect ratio of the via-hole is greater than or equal to 0.2 and less than or equal to 3, thereby a thickness uniformity of the backside-metal layer is improved.

### FIELD OF THE INVENTION

The present invention is related to a semiconductor integrated circuit, especially a semiconductor integrated circuit with a substrate via hole having a small aspect ratio.

### BACKGROUND OF THE INVENTION

Please refer to FIG. 3, which is a schematic cross-sectional view of an embodiment of a semiconductor integrated circuit of conventional technology. The semiconductor integrated circuit 9 of conventional technology comprises a semiconductor substrate 90, a front-side metal layer 95, a seed metal layer 91 and a backside metal layer 92. The semiconductor substrate 90 has a substrate via hole 93, a top surface 96 and a bottom surface 97. The front-side metal layer 95 is formed on the top surface 96 of the semiconductor substrate 90. The substrate via hole 93 penetrates the semiconductor substrate 90. The substrate via hole 93 has an inner surface 94. The inner surface 94 of the substrate via hole 93 includes a bottom and a surrounding. The bottom of the inner surface 94 of the substrate via hole 93 is defined by the front-side metal layer 95. The surrounding of the inner surface 94 of the substrate via hole 93 is defined by the semiconductor substrate 90. The seed metal layer 91 is formed on the inner surface 94 of the substrate via hole 93 and the bottom surface 97 of the semiconductor substrate 90. The seed metal layer 91 has an outer surface. The backside metal layer 92 is formed on the outer surface of the seed metal layer 91. The substrate via hole 93 has a depth D9, a width W90 and an aspect ratio, wherein the aspect ratio of the substrate via hole 93=D9/W90. In general, the aspect ratio of the substrate via hole 93 of conventional technology is greater than or equal to 8. However, the aspect ratio of the substrate via hole 93 of conventional technology is too high such that the thickness of the seed metal layer 91 is non-uniform and also such that the thickness of the backside metal layer 92 is non-uniform, especially, the thickness of the seed metal layer 91 formed on the inner surface 94 of the substrate via hole 93 and the thickness of the backside metal layer 92 formed on the outer surface (in the substrate via hole 93) of the seed metal layer 91 are particularly non-uniform. Please refer to FIG. 4A, which is a cross-sectional image of the scanning electron microscope of an embodiment of a semiconductor integrated circuit of conventional technology. Please also refer to FIGS. 4B, 4C and 4D, which are respectively partial enlargements of Y1, Y2 and Y3 blocks of the embodiment of FIG. 4A of conventional technology. In the embodiment of FIG. 4A of conventional technology, even though the aspect ratio of the substrate via hole 93 is already as small as approximately 3.5, however, from FIGS. 4B, 4C and 4D, it is very clear that the thickness of the seed metal layer 91 is distributed at 0.234 μm, 0.103 μm, 0.150 μm, and 0.103 μm; while the thickness of the backside metal layer 92 is distributed at 3.469 μm, 2.766 μm, 1.884 μm, and 2.259 μm. That is that the ratio of the thicker seed metal layer 91 and the thinner seed metal layer 91 is as high as approximately 2.27; while the ratio of the thicker backside metal layer 92 and the thinner backside metal layer 92 is as high as approximately 1.84.

When the uniformity of the thickness of the seed metal layer 91 formed on the inner surface 94 of the substrate via hole 93 is poor, it is possible that the thickness of the seed metal layer 91 in some area is too thin. It will cause the peeling phenomenon between the seed metal layer 91 and the semiconductor substrate 90 under high humidity and high temperature reliability test and cause damage to the reliability of the semiconductor integrated circuit 9. Furthermore, when the uniformity of the thickness of the seed metal layer 91 and the uniformity of the thickness of the backside metal layer 92 are poor, it will raise the resistance value of the seed metal layer 91 and the backside metal layer 92, especially, the resistance value of the seed metal layer 91 and the backside metal layer 92 formed in the substrate via hole 93 is particularly raised. Thereby, the heat dissipation of the semiconductor integrated circuit 9 of conventional technology is significantly raised such that the power consumption of the semiconductor integrated circuit 9 of the conventional technology is significantly raised. Moreover, since the resistance value of the seed metal layer 91 and the backside metal layer 92 is significantly raised, the heat is accumulated, especially in the substrate via hole 93. It is more possible to cause the peeling phenomenon between the seed metal layer 91 and the semiconductor substrate 90, and to cause damage to the reliability of the semiconductor integrated circuit 9. Furthermore, the seed metal layer 91 and the backside metal layer 92 formed in the substrate via hole 93 have an inductance value. Since the thickness of the seed metal layer 91 and the thickness of the backside metal layer 92 formed in the substrate via hole 93 are particularly non-uniform, such that a variation of the inductance value of the seed metal layer 91 and the backside metal layer 92 (in the substrate via hole 93) is significantly great. It affects the performance and the characteristics of the semiconductor integrated circuit 9 of conventional technology. Especially, when the semiconductor integrated circuit 9 of conventional technology is a high frequency circuit and the substrate via hole 93 is a hot via, the variation of the inductance value of the seed metal layer 91 and the backside metal layer 92 (in the substrate via hole 93) affects the performance and the characteristics of high frequency circuits greatly.

Accordingly, the present invention has developed a new design which may avoid the above mentioned drawbacks, may significantly enhance the performance of the devices and may take into account economic considerations. Therefore, the present invention then has been invented.

### SUMMARY OF THE INVENTION

The main technical problems that the present invention is seeking to solve are: 1. To improve the thickness uniformity of the seed metal layer and the back metal layer to avoid the peeling phenomenon between the seed metal layer and the semiconductor substrate, and avoid damaging to the reliability of the semiconductor integrated circuit; and to reduce the heat dissipation of the semiconductor integrated circuit to reduce the power consumption of the semiconductor integrated circuit; and 2. To reduce the variation of the inductance value of the seed metal layer and the back metal layer to avoid affecting the performance and the characteristics of the semiconductor integrated circuit.

In order to solve the problems mentioned the above and to achieve the expected effect, the present invention provides a semiconductor integrated circuit which comprises a semiconductor substrate, a first circuit layout and a second circuit layout. The semiconductor substrate has a first substrate via hole, a top surface and a bottom surface, the first substrate via hole has an inner surface, the inner surface of the first substrate via hole includes a bottom and a surrounding, the surrounding of the inner surface of the first substrate via hole is at least partially defined by the semiconductor substrate. The first circuit layout comprises a front-side metal layer. The front-side metal layer is formed on the top surface of the semiconductor substrate, wherein the bottom of the inner surface of the first substrate via hole is at least partially defined by the front-side metal layer. The second circuit layout comprises a seed metal layer and a backside metal layer. The seed metal layer is formed on the inner surface of the first substrate via hole and the bottom surface of the semiconductor substrate, wherein the seed metal layer has an outer surface. The backside metal layer is formed on the outer surface of the seed metal layer. The first substrate via hole has an aspect ratio, the aspect ratio of the first substrate via hole is greater than or equal to 0.2 and less than or equal to 3, thereby a thickness uniformity of the backside metal layer is improved. Thereby, the peeling phenomenon between the seed metal layer and the semiconductor substrate can be avoided, and thereby avoiding damage to the reliability of the semiconductor integrated circuit can be avoided. Moreover, the heat dissipation of the semiconductor integrated circuit is significantly reduced such that the power consumption of the semiconductor integrated circuit is significantly reduced.

The present invention further provides a semiconductor integrated circuit which comprises a semiconductor substrate, a first circuit layout and a second circuit layout. The semiconductor substrate has a first substrate via hole, a top surface and a bottom surface, the first substrate via hole has an inner surface, the inner surface of the first substrate via hole includes a bottom and a surrounding, the surrounding of the inner surface of the first substrate via hole is at least partially defined by the semiconductor substrate. The first circuit layout comprises a front-side metal layer. The front-side metal layer is formed on the top surface of the semiconductor substrate, wherein the bottom of the inner surface of the first substrate via hole is at least partially defined by the front-side metal layer. The second circuit layout comprises a seed metal layer and a backside metal layer. The seed metal layer is formed on the inner surface of the first substrate via hole and the bottom surface of the semiconductor substrate, wherein the seed metal layer has an outer surface. The backside metal layer is formed on the outer surface of the seed metal layer. The first substrate via hole has a depth and a width, the depth of the first substrate via hole is greater than or equal to 10 μm and less than or equal to 40 μm, the width of the first substrate via hole is greater than or equal to 5 μm and less than or equal to 50 μm, thereby a thickness uniformity of the backside metal layer is improved. Thereby, the peeling phenomenon between the seed metal layer and the semiconductor substrate can be avoided, and thereby avoiding damage to the reliability of the semiconductor integrated circuit can be avoided. Moreover, the heat dissipation of the semiconductor integrated circuit is significantly reduced such that the power consumption of the semiconductor integrated circuit is significantly reduced.

In an embodiment, the seed metal layer includes a first-substrate-via-hole-bottom seed metal layer formed on the bottom of the inner surface of the first substrate via hole, a first-substrate-via-hole-surrounding seed metal layer formed on the surrounding of the inner surface of the first substrate via hole, and a first-substrate-bottom-surface seed metal layer formed on the bottom surface of the semiconductor substrate; wherein the outer surface of the seed metal layer includes an outer surface of the first-substrate-via-hole-bottom seed metal layer, an outer surface of the first-substrate-via-hole-surrounding seed metal layer, and an outer surface of the first-substrate-bottom-surface seed metal layer; wherein the backside metal layer includes a first-substrate-via-hole-bottom backside metal layer formed on the outer surface of the first-substrate-via-hole-bottom seed metal layer, a first-substrate-via-hole-surrounding backside metal layer formed on the outer surface of the first-substrate-via-hole-surrounding seed metal layer, and a first-substrate-bottom-surface backside metal layer formed on the outer surface of the first-substrate-bottom-surface seed metal layer; wherein the second circuit layout includes a first-substrate-via-hole-bottom connection part, a first substrate via hole inductor, and a first electrical connection part; the first-substrate-via-hole-bottom connection part includes the first-substrate-via-hole-bottom seed metal layer and the first-substrate-via-hole-bottom backside metal layer; the first substrate via hole inductor includes the first-substrate-via-hole-surrounding seed metal layer and the first-substrate-via-hole-surrounding backside metal layer; the first electrical connection part includes the first-substrate-bottom-surface seed metal layer and the first-substrate-bottom-surface backside metal layer; wherein the first substrate via hole inductor is a hot via inductor.

The present invention further provides a semiconductor integrated circuit which comprises a semiconductor substrate, a first circuit layout and a second circuit layout. The semiconductor substrate has a first substrate via hole, a top surface and a bottom surface, the first substrate via hole has an inner surface, the inner surface of the first substrate via hole includes a bottom and a surrounding, the surrounding of the inner surface of the first substrate via hole is at least partially defined by the semiconductor substrate. The first circuit layout comprises a front-side metal layer. The front-side metal layer is formed on the top surface of the semiconductor substrate, wherein the bottom of the inner surface of the first substrate via hole is at least partially defined by the front-side metal layer. The second circuit layout comprises a seed metal layer and a backside metal layer. The seed metal layer is formed on the inner surface of the first substrate via hole and the bottom surface of the semiconductor substrate, wherein the seed metal layer includes a first-substrate-via-hole-bottom seed metal layer formed on the bottom of the inner surface of the first substrate via hole, a first-substrate-via-hole-surrounding seed metal layer formed on the surrounding of the inner surface of the first substrate via hole, and a first-substrate-bottom-surface seed metal layer formed on the bottom surface of the semiconductor substrate; wherein the first-substrate-via-hole-bottom seed metal layer is electrically connected to the front-side metal layer; wherein the seed metal layer has an outer surface; wherein the outer surface of the seed metal layer includes an outer surface of the first-substrate-via-hole-bottom seed metal layer, an outer surface of the first-substrate-via-hole-surrounding seed metal layer, and an outer surface of the first-substrate-bottom-surface seed metal layer. The backside metal layer is formed on the outer surface of the seed metal layer; wherein the backside metal layer includes a first-substrate-via-hole-bottom backside metal layer formed on the outer surface of the first-substrate-via-hole-bottom seed metal layer, a first-substrate-via-hole-surrounding backside metal layer formed on the outer surface of the first-substrate-via-hole-surrounding seed metal layer, and a first-substrate-bottom-surface backside metal layer formed on the outer surface of the first-substrate-bottom-surface seed metal layer. The second circuit layout includes a first-substrate-via-hole-bottom connection part, a first substrate via hole inductor, and a first electrical connection part; the first-substrate-via-hole-bottom connection part includes the first-substrate-via-hole-bottom seed metal layer and the first-substrate-via-hole-bottom backside metal layer; the first substrate via hole inductor includes the first-substrate-via-hole-surrounding seed metal layer and the first-substrate-via-hole-surrounding backside metal layer; the first electrical connection part includes the first-substrate-bottom-surface seed metal layer and the first-substrate-bottom-surface backside metal layer; wherein the first substrate via hole inductor is a hot via inductor.

In an embodiment, the first substrate via hole has a width, the width of the first substrate via hole is greater than or equal to 5 μm and less than or equal to 50 μm.

In an embodiment, the first substrate via hole has a depth, the depth of the first substrate via hole is greater than or equal to 10 μm and less than or equal to 40 μm.

In an embodiment, the semiconductor integrated circuit is electrically connected to an RF signal output terminal or an RF signal input terminal through the first electrical connection part.

In an embodiment, the first substrate via hole inductor has a first inductance value, wherein the first inductance value of the first substrate via hole inductor is greater than or equal to 0.1 pH (picohenry) and less than or equal to 17.0 pH.

In an embodiment, the front-side metal layer comprises a first part and a second part, the bottom of the inner surface of the first substrate via hole is at least partially defined by the first part of the front-side metal layer; the first-substrate-via-hole-bottom seed metal layer is electrically connected to the first part of the front-side metal layer; wherein the semiconductor substrate further includes a second substrate via hole, the second substrate via hole has an inner surface, the inner surface of the second substrate via hole includes a bottom and a surrounding, the surrounding of the inner surface of the second substrate via hole is at least partially defined by the semiconductor substrate, the bottom of the inner surface of the second substrate via hole is at least partially defined by the second part of the front-side metal layer; the bottom surface of the semiconductor substrate comprises a first area, a second area, and a separation area, the separation area separates the first area of the bottom surface of the semiconductor substrate from the second area of the bottom surface of the semiconductor substrate; wherein the seed metal layer is formed on the inner surface of the first substrate via hole, the inner surface of the second substrate via hole, the first area of the bottom surface of the semiconductor substrate, and the second area of the bottom surface of the semiconductor substrate; the first-substrate-bottom-surface seed metal layer is formed on the first area of the bottom surface of the semiconductor substrate; the seed metal layer further includes a second-substrate-via-hole-bottom seed metal layer formed on the bottom of the inner surface of the second substrate via hole, a second-substrate-via-hole-surrounding seed metal layer formed on the surrounding of the inner surface of the second substrate via hole, and a second-substrate-bottom-surface seed metal layer formed on the second area of the bottom surface of the semiconductor substrate; the second-substrate-via-hole-bottom seed metal layer is electrically connected to the second part of the front-side metal layer; wherein the outer surface of the seed metal layer further includes an outer surface of the second-substrate-via-hole-bottom seed metal layer, an outer surface of the second-substrate-via-hole-surrounding seed metal layer, and an outer surface of the second-substrate-bottom-surface seed metal layer; wherein the backside metal layer further includes a second-substrate-via-hole-bottom backside metal layer formed on the outer surface of the second-substrate-via-hole-bottom seed metal layer, a second-substrate-via-hole-surrounding backside metal layer formed on the outer surface of the second-substrate-via-hole-surrounding seed metal layer, and a second-substrate-bottom-surface backside metal layer formed on the outer surface of the second-substrate-bottom-surface seed metal layer; wherein the second circuit layout further includes a second-substrate-via-hole-bottom connection part, a second substrate via hole inductor, and a second electrical connection part; the second-substrate-via-hole-bottom connection part includes the second-substrate-via-hole-bottom seed metal layer and the second-substrate-via-hole-bottom backside metal layer; the second substrate via hole inductor includes the second-substrate-via-hole-surrounding seed metal layer and the second-substrate-via-hole-surrounding backside metal layer; the second electrical connection part includes the second-substrate-bottom-surface seed metal layer and the second-substrate-bottom-surface backside metal layer.

In an embodiment, the second substrate via hole inductor is a hot via inductor.

In an embodiment, the semiconductor integrated circuit is electrically connected to one of an RF signal output terminal and an RF signal input terminal through the first electrical connection part, and the semiconductor integrated circuit is electrically connected to the other of the RF signal output terminal and the RF signal input terminal through the second electrical connection part.

In an embodiment, the second substrate via hole inductor is a non-hot via inductor, the semiconductor integrated circuit is grounded through the second electrical connection part.

In an embodiment, the second substrate via hole has an aspect ratio, the aspect ratio of the second substrate via hole is greater than or equal to 0.2 and less than or equal to 3.

In an embodiment, the second substrate via hole has a width, the width of the second substrate via hole is greater than or equal to 5 μm and less than or equal to 50 μm.

In an embodiment, the second substrate via hole has a depth, the depth of the second substrate via hole is greater than or equal to 10 μm and less than or equal to 40 μm.

In an embodiment, the second substrate via hole inductor has a second inductance value, wherein the second inductance value of the second substrate via hole inductor is greater than or equal to 0.1 pH and less than or equal to 17.0 pH.

In an embodiment, the semiconductor integrated circuit is an RF circuit.

In an embodiment, the semiconductor substrate has a thickness, the thickness of the semiconductor substrate is greater than or equal to 10 μm and less than or equal to 40 μm.

In an embodiment, the seed metal layer has a thickness, the thickness of the seed metal layer is greater than or equal to 0.1 μm and less than or equal to 1 μm.

In an embodiment, the backside metal layer has a thickness, the thickness of the backside metal layer is greater than or equal to 1 μm and less than or equal to 10 μm.

In an embodiment, the seed metal layer is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy.

In an embodiment, the backside metal layer is made by at least one material selected from the group consisting of: Au and Cu.

In an embodiment, the semiconductor substrate is made by one material selected from the group consisting of: GaAs, InP, GaN, sapphire and SiC.

The present invention further provides a circuit layout method for semiconductor integrated circuit, which comprises following steps of: Step A0: designing a first-substrate-via-hole shape, a first-substrate-via-hole depth and a first-substrate-via-hole width of a first substrate via hole, a seed-metal-layer thickness of a seed metal layer, and a backside-metal-layer thickness of a backside metal layer, such that a first substrate via hole inductor has a first inductance value; Step A1: forming a first circuit layout on a top surface of a semiconductor substrate, wherein the first circuit layout comprises a front-side metal layer; Step B1: etching the semiconductor substrate to form the first substrate via hole such that the first substrate via hole has the first-substrate-via-hole shape, the first-substrate-via-hole depth, and the first-substrate-via-hole width, wherein the first substrate via hole has an inner surface, the inner surface of the first substrate via hole includes a bottom and a surrounding, wherein the bottom of the inner surface of the first substrate via hole is at least partially defined by the front-side metal layer, the surrounding of the inner surface of the first substrate via hole is at least partially defined by the semiconductor substrate; and Step C1: forming a second circuit layout, which comprises following steps of: Step C10: forming the seed metal layer on the inner surface of the first substrate via hole and a bottom surface of the semiconductor substrate such that the seed metal layer has the seed-metal-layer thickness, wherein the seed metal layer includes a first-substrate-via-hole-bottom seed metal layer formed on the bottom of the inner surface of the first substrate via hole, a first-substrate-via-hole-surrounding seed metal layer formed on the surrounding of the inner surface of the first substrate via hole, and a first-substrate-bottom-surface seed metal layer formed on the bottom surface of the semiconductor substrate; wherein the first-substrate-via-hole-bottom seed metal layer is electrically connected to the front-side metal layer; wherein the seed metal layer has an outer surface; wherein the outer surface of the seed metal layer includes an outer surface of the first-substrate-via-hole-bottom seed metal layer, an outer surface of the first-substrate-via-hole-surrounding seed metal layer, and an outer surface of the first-substrate-bottom-surface seed metal layer; and Step C11: forming the backside metal layer on the outer surface of the seed metal layer such that the backside metal layer has the backside-metal-layer thickness, wherein the backside metal layer includes a first-substrate-via-hole-bottom backside metal layer formed on the outer surface of the first-substrate-via-hole-bottom seed metal layer, a first-substrate-via-hole-surrounding backside metal layer formed on the outer surface of the first-substrate-via-hole-surrounding seed metal layer, and a first-substrate-bottom-surface backside metal layer formed on the outer surface of the first-substrate-bottom-surface seed metal layer; wherein the second circuit layout includes a first-substrate-via-hole-bottom connection part, a first substrate via hole inductor, and a first electrical connection part; the first-substrate-via-hole-bottom connection part includes the first-substrate-via-hole-bottom seed metal layer and the first-substrate-via-hole-bottom backside metal layer; the first substrate via hole inductor includes the first-substrate-via-hole-surrounding seed metal layer and the first-substrate-via-hole-surrounding backside metal layer; the first electrical connection part includes the first-substrate-bottom-surface seed metal layer and the first-substrate-bottom-surface backside metal layer.

In an embodiment, the first substrate via hole has an aspect ratio, the aspect ratio of the first substrate via hole is greater than or equal to 0.2 and less than or equal to 3.

In an embodiment, the first-substrate-via-hole width is greater than or equal to 5 μm and less than or equal to 50 μm.

In an embodiment, the first-substrate-via-hole depth is greater than or equal to 10 μm and less than or equal to 40 μm.

In an embodiment, the first inductance value of the first substrate via hole inductor is greater than or equal to 0.1 pH and less than or equal to 17.0 pH.

In an embodiment, the first substrate via hole inductor is a hot via inductor.

In an embodiment, the semiconductor integrated circuit is electrically connected to an RF signal output terminal or an RF signal input terminal through the first electrical connection part.

In an embodiment, the first substrate via hole inductor is a non-hot via inductor, the semiconductor integrated circuit is grounded through the first electrical connection part.

In an embodiment, the front-side metal layer comprises a first part and a second part, the bottom of the inner surface of the first substrate via hole is at least partially defined by the first part of the front-side metal layer; the first-substrate-via-hole-bottom seed metal layer is electrically connected to the first part of the front-side metal layer; wherein the Step A10 further comprises a following step of: designing a second-substrate-via-hole shape, a second-substrate-via-hole depth and a second-substrate-via-hole width of a second substrate via hole such that a second substrate via hole inductor has a second inductance value; wherein the Step B1 further comprises a following step of: etching the semiconductor substrate to form the second substrate via hole such that the second substrate via hole has the second-substrate-via-hole shape, the second-substrate-via-hole depth, and the second-substrate-via-hole width, wherein the second substrate via hole has an inner surface, the inner surface of the second substrate via hole includes a bottom and a surrounding, wherein the bottom of the inner surface of the second substrate via hole is at least partially defined by the second part of the front-side metal layer, the surrounding of the inner surface of the second substrate via hole is at least partially defined by the semiconductor substrate; wherein the bottom surface of the semiconductor substrate comprises a first area, a second area, and a separation area, the separation area separates the first area of the bottom surface of the semiconductor substrate from the second area of the bottom surface of the semiconductor substrate; wherein the seed metal layer is formed on the inner surface of the first substrate via hole, the inner surface of the second substrate via hole, the first area of the bottom surface of the semiconductor substrate, and the second area of the bottom surface of the semiconductor substrate; the first-substrate-bottom-surface seed metal layer is formed on the first area of the bottom surface of the semiconductor substrate; the seed metal layer further includes a second-substrate-via-hole-bottom seed metal layer formed on the bottom of the inner surface of the second substrate via hole, a second-substrate-via-hole-surrounding seed metal layer formed on the surrounding of the inner surface of the second substrate via hole, and a second-substrate-bottom-surface seed metal layer formed on the second area of the bottom surface of the semiconductor substrate; the second-substrate-via-hole-bottom seed metal layer is electrically connected to the second part of the front-side metal layer; wherein the outer surface of the seed metal layer further includes an outer surface of the second-substrate-via-hole-bottom seed metal layer, an outer surface of the second-substrate-via-hole-surrounding seed metal layer, and an outer surface of the second-substrate-bottom-surface seed metal layer; wherein the backside metal layer is formed on the outer surface of the first-substrate-via-hole-bottom seed metal layer, the outer surface of the first-substrate-via-hole-surrounding seed metal layer, the outer surface of the first-substrate-bottom-surface seed metal layer, the outer surface of the second-substrate-via-hole-bottom seed metal layer, the outer surface of the second-substrate-via-hole-surrounding seed metal layer, and the outer surface of the second-substrate-bottom-surface seed metal layer; wherein the backside metal layer further includes a second-substrate-via-hole-bottom backside metal layer formed on the outer surface of the second-substrate-via-hole-bottom seed metal layer, a second-substrate-via-hole-surrounding backside metal layer formed on the outer surface of the second-substrate-via-hole-surrounding seed metal layer, and a second-substrate-bottom-surface backside metal layer formed on the outer surface of the second-substrate-bottom-surface seed metal layer; wherein the second circuit layout further includes a second-substrate-via-hole-bottom connection part, a second substrate via hole inductor, and a second electrical connection part; the second-substrate-via-hole-bottom connection part includes the second-substrate-via-hole-bottom seed metal layer and the second-substrate-via-hole-bottom backside metal layer; the second substrate via hole inductor includes the second-substrate-via-hole-surrounding seed metal layer and the second-substrate-via-hole-surrounding backside metal layer; the second electrical connection part includes the second-substrate-bottom-surface seed metal layer and the second-substrate-bottom-surface backside metal layer.

In an embodiment, the second substrate via hole has an aspect ratio, the aspect ratio of the second substrate via hole is greater than or equal to 0.2 and less than or equal to 3.

In an embodiment, the second-substrate-via-hole width is greater than or equal to 5 μm and less than or equal to 50 μm.

In an embodiment, the second-substrate-via-hole depth is greater than or equal to 10 μm and less than or equal to 40 μm.

In an embodiment, the second inductance value of the second substrate via hole inductor is greater than or equal to 0.1 pH and less than or equal to 17.0 pH.

In an embodiment, the second substrate via hole inductor is a hot via inductor.

In an embodiment, the semiconductor integrated circuit is electrically connected to one of an RF signal output terminal and an RF signal input terminal through the second electrical connection part.

In an embodiment, the first substrate via hole inductor and the second substrate via hole inductor are respectively a hot via inductor.

In an embodiment, the semiconductor integrated circuit is electrically connected to one of an RF signal output terminal and an RF signal input terminal through the first electrical connection part, and the semiconductor integrated circuit is electrically connected to the other of the RF signal output terminal and the RF signal input terminal through the second electrical connection part.

In an embodiment, the second substrate via hole inductor is a non-hot via inductor, the semiconductor integrated circuit is grounded through the second electrical connection part.

In an embodiment, the semiconductor integrated circuit is an RF circuit.

In an embodiment, after the Step A1 and before the Step B1, the circuit layout method further comprises a following step of: thinning the semiconductor substrate such that the semiconductor substrate has a thickness greater than or equal to 10 μm and less than or equal to 40 μm.

In an embodiment, the seed-metal-layer thickness of the seed metal layer is greater than or equal to 0.1 μm and less than or equal to 1 μm.

In an embodiment, the backside-metal-layer thickness of the backside metal layer is greater than or equal to 1 μm and less than or equal to 10 μm.

In an embodiment, the seed metal layer is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy.

In an embodiment, the backside metal layer is made by at least one material selected from the group consisting of: Au and Cu.

In an embodiment, the semiconductor substrate is made by one material selected from the group consisting of: GaAs, InP, GaN, sapphire and SiC.

For further understanding the characteristics and effects of the present invention, some preferred embodiments referred to drawings are in detail described as follows.

### BRIEF DESCRIPTION OF DRAWINGS

FIG. 1A is a schematic top view of an embodiment of a semiconductor integrated circuit of the present invention.

FIG. 1B is a schematic cross-sectional view taken along the section line A-A′ of the embodiment of FIG. 1A.

FIG. 1C is a schematic cross-sectional view showing a step of a circuit layout method for semiconductor integrated circuit of the present invention for fabricating the embodiment of FIGS. 1A and 1B.

FIG. 1D is a schematic cross-sectional view showing another step of a circuit layout method for semiconductor integrated circuit of the present invention for fabricating the embodiment of FIGS. 1A and 1B.

FIG. 1E is a schematic cross-sectional view showing another step of a circuit layout method for semiconductor integrated circuit of the present invention for fabricating the embodiment of FIGS. 1A and 1B.

FIG. 1F is a schematic top view of another embodiment of a semiconductor integrated circuit of the present invention.

FIG. 1G is a schematic cross-sectional view taken along the section line B-B′ of the embodiment of FIG. 1F.

FIG. 1H is a schematic cross-sectional view showing a step of a circuit layout method for semiconductor integrated circuit of the present invention for fabricating the embodiment of FIGS. 1F and 1G.

FIG. 1I is a schematic cross-sectional view showing another step of a circuit layout method for semiconductor integrated circuit of the present invention for fabricating the embodiment of FIGS. 1F and 1G.

FIG. 1J is a schematic cross-sectional view showing another step of a circuit layout method for semiconductor integrated circuit of the present invention for fabricating the embodiment of FIGS. 1F and 1G.

FIG. 1K is a schematic top view of another embodiment of a semiconductor integrated circuit of the present invention.

FIG. 1L is a schematic cross-sectional view taken along the section line C-C′ of the embodiment of FIG. 1K.

FIG. 1M is a schematic cross-sectional view showing a step of a circuit layout method for semiconductor integrated circuit of the present invention for fabricating the embodiment of FIGS. 1K and 1L.

FIG. 1N is a schematic cross-sectional view showing another step of a circuit layout method for semiconductor integrated circuit of the present invention for fabricating the embodiment of FIGS. 1K and 1L.

FIG. 1O is a schematic cross-sectional view showing another step of a circuit layout method for semiconductor integrated circuit of the present invention for fabricating the embodiment of FIGS. 1K and 1L.

FIG. 1P is a cross-sectional image of the scanning electron microscope of an embodiment of a semiconductor integrated circuit of the present invention.

FIG. 1Q is a partial enlargement of X1 block of the embodiment of FIG. 1P of the present invention.

FIG. 1R is a partial enlargement of X2 block of the embodiment of FIG. 1P of the present invention.

FIG. 1S is a partial enlargement of X3 block of the embodiment of FIG. 1P of the present invention.

FIG. 1T is a comparison chart of the resistance measurement of the second circuit layout of the embodiment of FIGS. 1A and 1B of the present invention and the resistance measurement of the embodiment of conventional technology.

FIG. 2A is a schematic top view of an embodiment of a semiconductor integrated circuit of the present invention.

FIG. 2B is a schematic cross-sectional view taken along the section line D-D′ of the embodiment of FIG. 2A.

FIG. 2C is a schematic cross-sectional view showing a step of a circuit layout method for semiconductor integrated circuit of the present invention for fabricating the embodiment of FIGS. 2A and 2B.

FIG. 2D is a schematic cross-sectional view showing another step of a circuit layout method for semiconductor integrated circuit of the present invention for fabricating the embodiment of FIGS. 2A and 2B.

FIG. 2E is a schematic cross-sectional view showing another step of a circuit layout method for semiconductor integrated circuit of the present invention for fabricating the embodiment of FIGS. 2A and 2B.

FIG. 2F is a schematic cross-sectional view of a application of the embodiment of FIGS. 2A and 2B of the present invention.

FIG. 3 is a schematic cross-sectional view of an embodiment of a semiconductor integrated circuit of conventional technology.

FIG. 4A is a cross-sectional image of the scanning electron microscope of an embodiment of a semiconductor integrated circuit of conventional technology.

FIG. 4B is a partial enlargement of Y1 block of the embodiment of FIG. 4A of conventional technology.

FIG. 4C is a partial enlargement of Y2 block of the embodiment of FIG. 4A of conventional technology.

FIG. 4D is a partial enlargement of Y3 block of the embodiment of FIG. 4A of conventional technology.

### DETAILED DESCRIPTIONS OF PREFERRED EMBODIMENTS

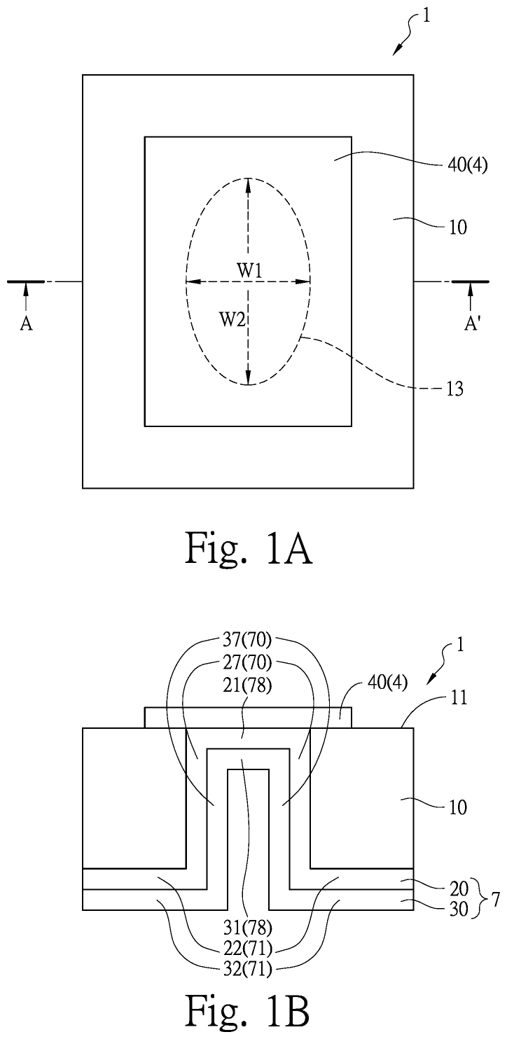

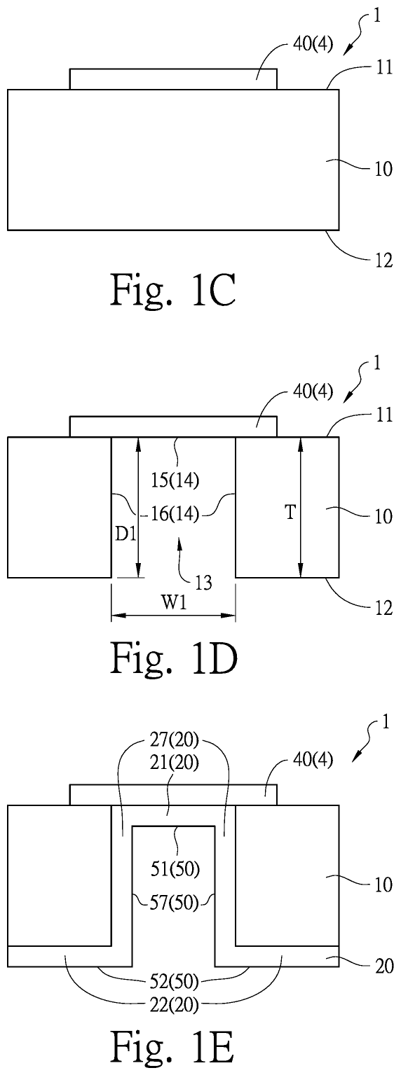

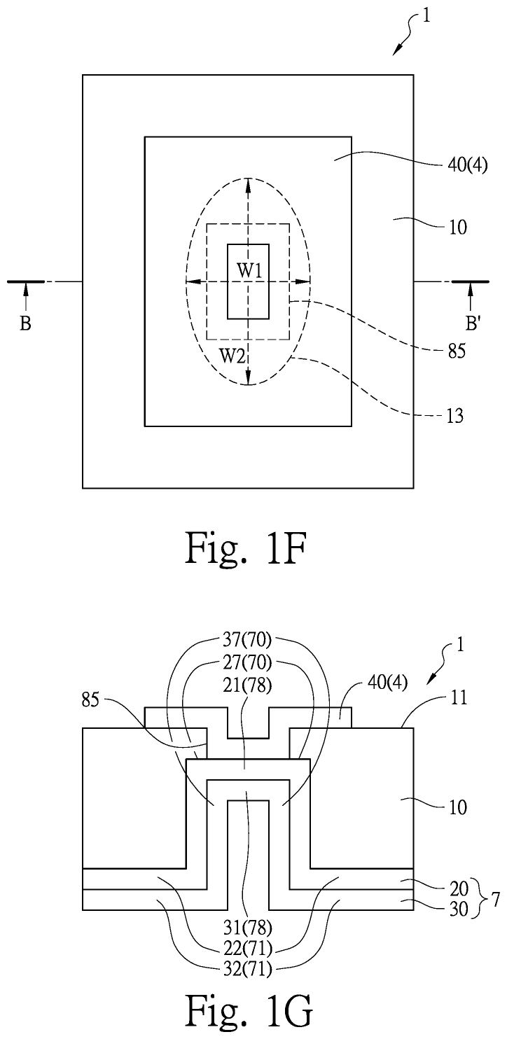

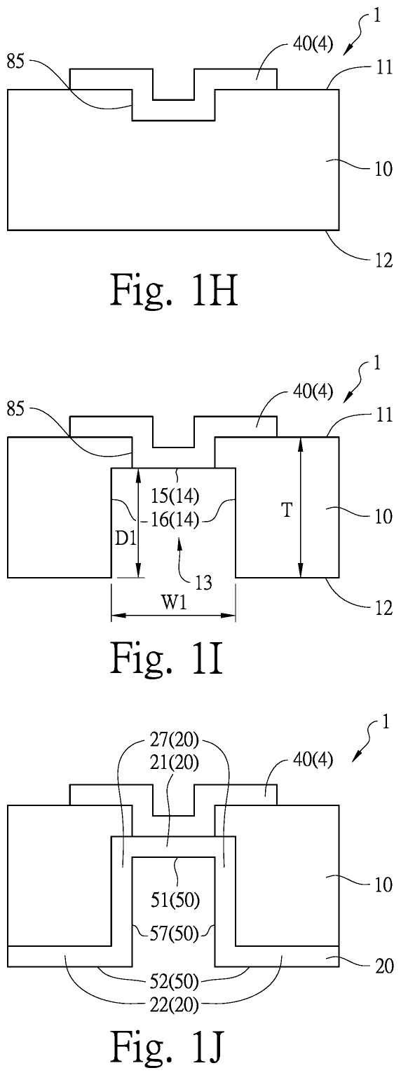

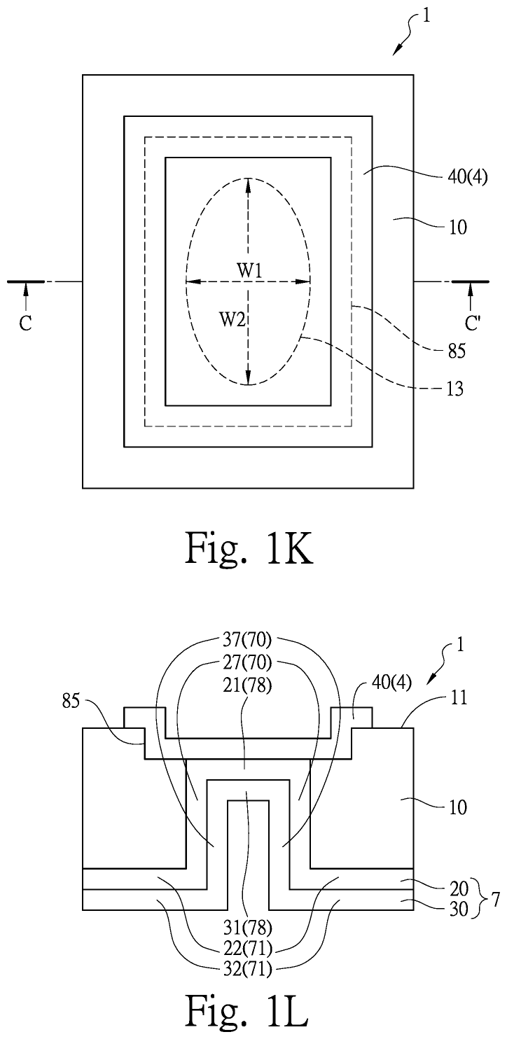

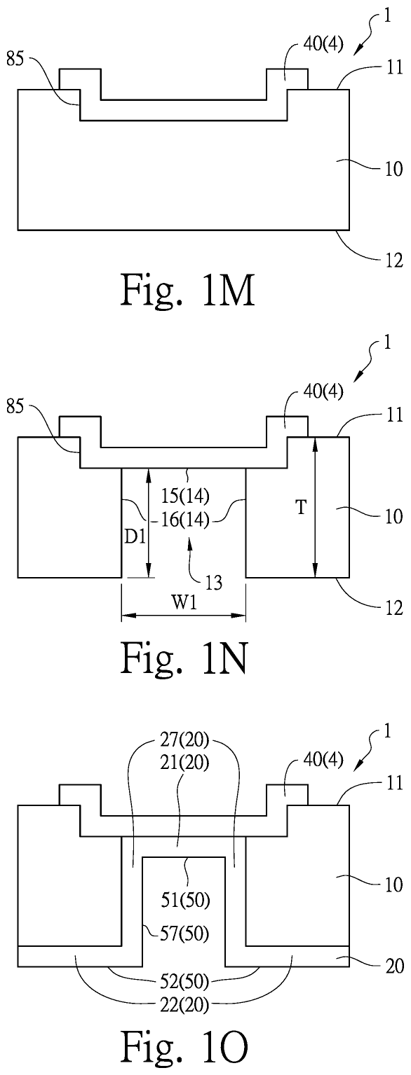

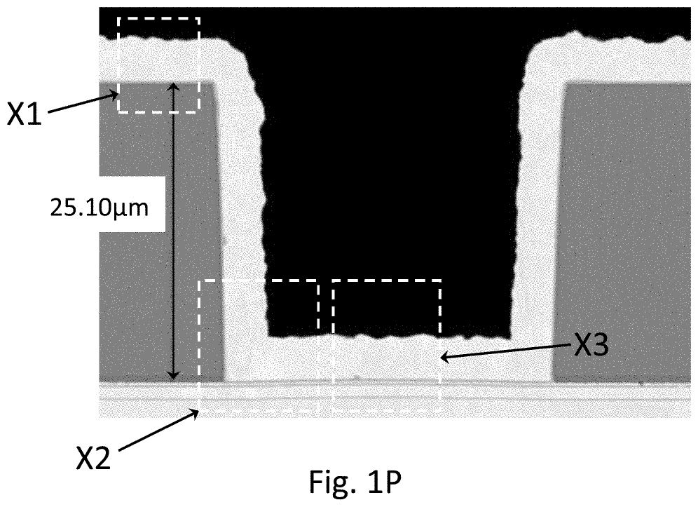

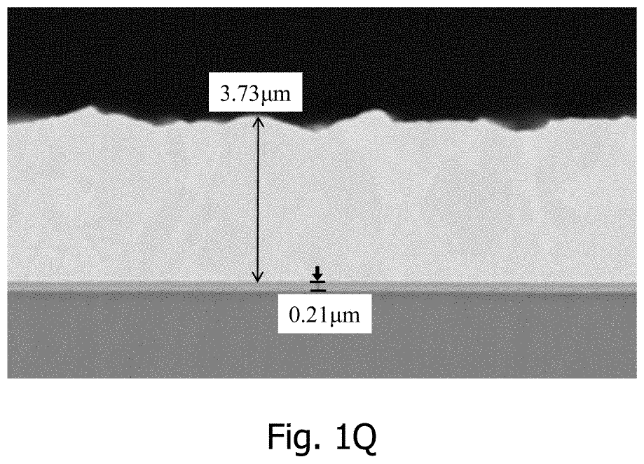

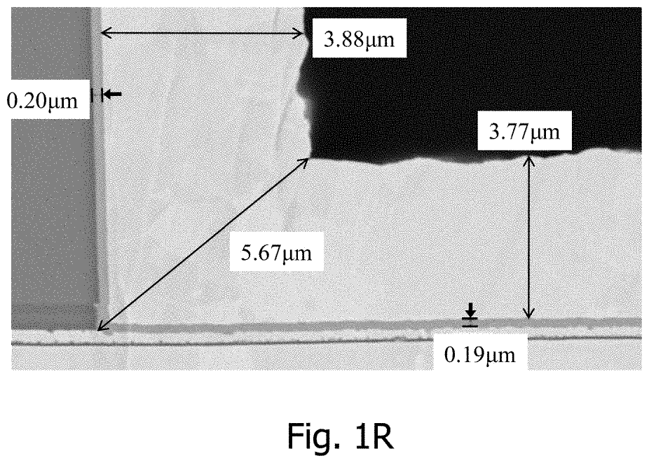

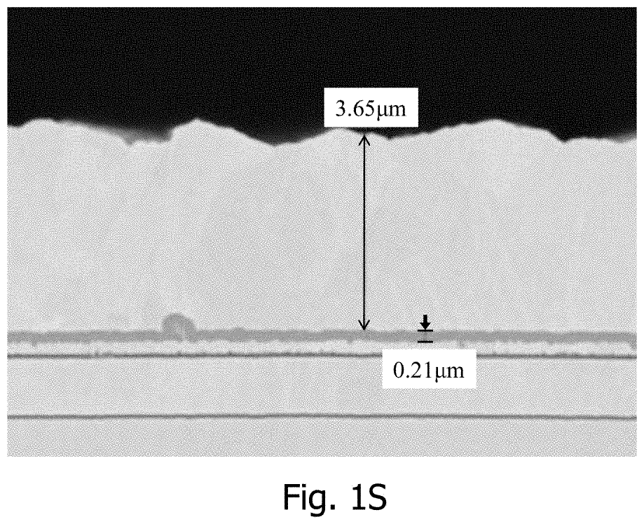

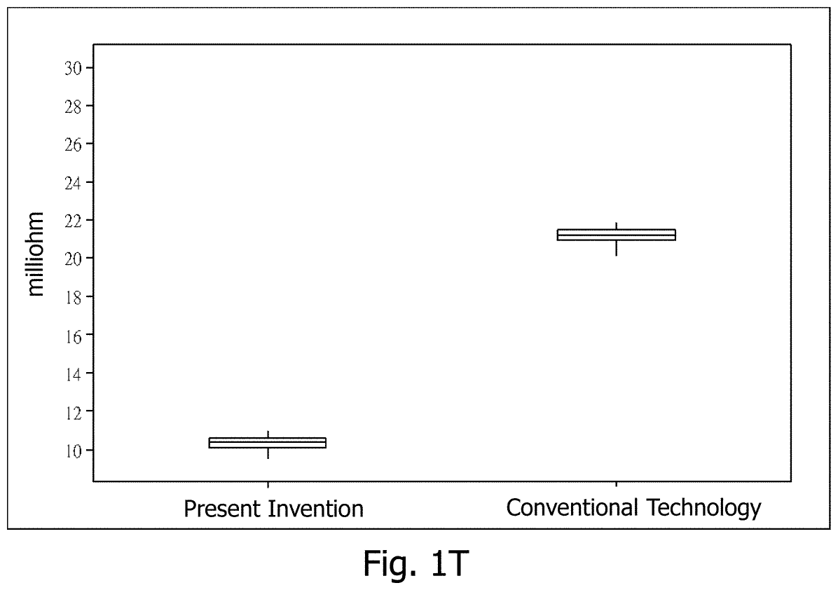

Please refer to FIG. 1A, which is a schematic top view of an embodiment of a semiconductor integrated circuit of the present invention. Please also refer to FIG. 1B, which is a schematic cross-sectional view taken along the section line A-A′ of the embodiment of FIG. 1A. A semiconductor integrated circuit 1 of the present invention comprises a semiconductor substrate 10, a first circuit layout 4 and a second circuit layout 7. The first circuit layout 4 comprises a front-side metal layer 40. The second circuit layout 7 comprises a seed metal layer 20 and a backside metal layer 30. The semiconductor substrate 10 has a substrate via hole 13, a top surface 11 and a bottom surface 12. A circuit layout method for semiconductor integrated circuit 1 of the present invention comprises following steps of: Step A1: (please also refer to FIG. 1C, which is a schematic cross-sectional view showing a step of a circuit layout method for semiconductor integrated circuit of the present invention for fabricating the embodiment of FIGS. 1A and 1B) forming the first circuit layout 4 on the top surface 11 of the semiconductor substrate 10, wherein the first circuit layout 4 comprises the front-side metal layer 40; Step B1: (please also refer to FIG. 1D, which is a schematic cross-sectional view showing another step of a circuit layout method for semiconductor integrated circuit of the present invention for fabricating the embodiment of FIGS. 1A and 1B) etching the semiconductor substrate 10 from the bottom surface 12 of the semiconductor substrate 10 to form the substrate via hole 13, wherein the substrate via hole 13 has an inner surface 14, the inner surface 14 of the substrate via hole 13 includes a bottom 15 and a surrounding 16; wherein the bottom 15 of the inner surface 14 of the substrate via hole 13 is defined by the front-side metal layer 40, the surrounding 16 of the inner surface 14 of the substrate via hole 13 is defined by the semiconductor substrate 10; wherein the semiconductor substrate 10 is made by one material selected from the group consisting of: GaAs, InP, GaN, sapphire and SiC; the semiconductor substrate 10 has a thickness T; wherein the substrate via hole 13 has a depth D1; in current embodiment, the thickness T of the semiconductor substrate 10 is equal to the depth D1 of the substrate via hole 13; and Step C1: forming the second circuit layout 7, wherein the Step C1 comprises following steps of: Step C11: (please also refer to FIG. 1E, which is a schematic cross-sectional view showing another step of a circuit layout method for semiconductor integrated circuit of the present invention for fabricating the embodiment of FIGS. 1A and 1B) forming the seed metal layer 20 on the inner surface 14 of the substrate via hole 13 and the bottom surface 12 of the semiconductor substrate 10; wherein the seed metal layer 20 includes a substrate-via-hole-bottom seed metal layer 21 formed on the bottom 15 of the inner surface 14 of the substrate via hole 13, a substrate-via-hole-surrounding seed metal layer 27 formed on the surrounding 16 of the inner surface 14 of the substrate via hole 13, and a substrate-bottom-surface seed metal layer 22 formed on the bottom surface 12 of the semiconductor substrate 10; wherein the substrate-via-hole-bottom seed metal layer 21 is electrically connected to the front-side metal layer 40; the seed metal layer 20 has an outer surface 50; wherein the outer surface 50 of the seed metal layer 20 includes an outer surface 51 of the substrate-via-hole-bottom seed metal layer 21, an outer surface 57 of the substrate-via-hole-surrounding seed metal layer 27, and an outer surface 52 of the substrate-bottom-surface seed metal layer 22; wherein the seed metal layer 20 is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy; in some embodiments, the seed metal layer 20 is deposited on the inner surface 14 of the substrate via hole 13 and the bottom surface 12 of the semiconductor substrate 10 by the method of sputtering or the method of electroless plating, etc.; and Step C12: (please also refer to FIGS. 1A and 1B) forming the backside metal layer 30 on the outer surface 50 of the seed metal layer 20, wherein the backside metal layer 30 includes a substrate-via-hole-bottom backside metal layer 31 formed on the outer surface 51 of the substrate-via-hole-bottom seed metal layer 21, a substrate-via-hole-surrounding backside metal layer 37 formed on the outer surface 57 of the substrate-via-hole-surrounding seed metal layer 27, and a substrate-bottom-surface backside metal layer 32 formed on the outer surface 52 of the substrate-bottom-surface seed metal layer 22; wherein the backside metal layer 30 is made by at least one material selected from the group consisting of: Au and Cu; in some embodiments, the backside metal layer 30 is deposited on the outer surface 50 of the seed metal layer 20 by the method of plating. The substrate via hole 13 has a depth, a width and an aspect ratio when the cross-sectional view is taken along a section line, wherein the aspect ratio=the depth D1/the width. In the embodiment of FIG. 1A, when the cross-sectional view is taken along the section line A-A′, the width=W1, and the aspect ratio=the depth D1/the width W1; while the cross-sectional view is taken along the section line perpendicular to A-A′, the width=W2, and

the aspect ratio=the depth D1/the width W2. When the cross-sectional view is taken along the section line, wherein the aspect ratio of the substrate via hole 13 is greater than or equal to 0.2 and less than or equal to 3 (i.e. 0.2≤the aspect ratio≤3), the aspect ratio of the substrate via hole 13 is small enough, so that when forming the seed metal layer 20 and the backside metal layer 30, the seed metal layer 20 can be uniformly deposited on the inner surface 14 of the substrate via hole 13 and the bottom surface 12 of the semiconductor substrate 10 and the backside metal layer 30 can be uniformly deposited on the outer surface 50 of the seed metal layer 20 (including the outer surface 51 of the substrate-via-hole-bottom seed metal layer 21, the outer surface 57 of the substrate-via-hole-surrounding seed metal layer 27, and the outer surface 52 of the substrate-bottom-surface seed metal layer 22), respectively. Thereby a thickness uniformity of the seed metal layer 20 (including the substrate-via-hole-bottom seed metal layer 21, the substrate-via-hole-surrounding seed metal layer 27, and the substrate-bottom-surface seed metal layer 22) can be significantly improved, and a thickness uniformity of the backside metal layer 30 (including the substrate-via-hole-bottom backside metal layer 31, the substrate-via-hole-surrounding backside metal layer 37, and the substrate-bottom-surface backside metal layer 32) can also be significantly improved too. Since the thickness uniformity of the seed metal layer 20 and the thickness uniformity of the backside metal layer 30 are both significantly improved such that a resistance of the second circuit layout 7 (including the seed metal layer 20 and the backside metal layer 30) is significantly reduced. Thereby, the heat dissipation of the semiconductor integrated circuit 1 of the present invention can be significantly reduced such that the power consumption of the semiconductor integrated circuit 1 of the present invention can be significantly reduced. Moreover, the peeling phenomenon between the seed metal layer 20 and the semiconductor substrate 10 can be prevented and thereby avoiding damage to the reliability of the semiconductor integrated circuit 1 of the present invention.

In some preferable embodiments, the depth D1 of the substrate via hole 13 is greater than or equal to 10 μm and less than or equal to 40 μm. In some embodiments, the depth D1 of the substrate via hole 13 is greater than or equal to 5 μm and less than or equal to 40 μm. In some embodiments, the depth D1 of the substrate via hole 13 is greater than or equal to 8 μm and less than or equal to 40 μm. In some embodiments, the depth D1 of the substrate via hole 13 is greater than or equal to 13 μm and less than or equal to 40 μm. In some embodiments, the depth D1 of the substrate via hole 13 is greater than or equal to 15 μm and less than or equal to 40 μm. In some embodiments, the depth D1 of the substrate via hole 13 is greater than or equal to 10 μm and less than or equal to 35 μm. In some embodiments, the depth D1 of the substrate via hole 13 is greater than or equal to 10 μm and less than or equal to 30 μm. In some embodiments, the depth D1 of the substrate via hole 13 is greater than or equal to 10 μm and less than or equal to 25 μm. In some embodiments, the depth D1 of the substrate via hole 13 is greater than or equal to 10 μm and less than or equal to 20 μm. In some embodiments, the depth D1 of the substrate via hole 13 is greater than or equal to 10 μm and less than or equal to 45 μm. In some embodiments, the depth D1 of the substrate via hole 13 is greater than or equal to 10 μm and less than or equal to 50 μm.

In some preferable embodiments, the width of the substrate via hole 13 is greater than or equal to 5 μm and less than or equal to 50 μm. In some embodiments, the width of the substrate via hole 13 is greater than or equal to 5 μm and less than or equal to 45 μm. In some embodiments, the width of the substrate via hole 13 is greater than or equal to 5 μm and less than or equal to 40 μm. In some embodiments, the width of the substrate via hole 13 is greater than or equal to 5 μm and less than or equal to 35 μm. In some embodiments, the width of the substrate via hole 13 is greater than or equal to 5 μm and less than or equal to 30 μm. In some embodiments, the width of the substrate via hole 13 is greater than or equal to 5 μm and less than or equal to 25 μm. In some embodiments, the width of the substrate via hole 13 is greater than or equal to 8 μm and less than or equal to 50 μm. In some embodiments, the width of the substrate via hole 13 is greater than or equal to 10 μm and less than or equal to 50 μm. In some embodiments, the width of the substrate via hole 13 is greater than or equal to 13 μm and less than or equal to 50 μm. In some embodiments, the width of the substrate via hole 13 is greater than or equal to 15 μm and less than or equal to 50 μm. In some embodiments, the width of the substrate via hole 13 is greater than or equal to 20 μm and less than or equal to 50 μm. In some embodiments, the width of the substrate via hole 13 is greater than or equal to 25 μm and less than or equal to 50 μm. In some embodiments, the width of the substrate via hole 13 is greater than or equal to 5 μm and less than or equal to 55 μm. In some embodiments, the width of the substrate via hole 13 is greater than or equal to 5 μm and less than or equal to 60 μm.

In some embodiments, the aspect ratio of the substrate via hole 13 is greater than or equal to 0.1 and less than or equal to 3. In some embodiments, the aspect ratio of the substrate via hole 13 is greater than or equal to 0.3 and less than or equal to 3. In some embodiments, the aspect ratio of the substrate via hole 13 is greater than or equal to 0.4 and less than or equal to 3. In some embodiments, the aspect ratio of the substrate via hole 13 is greater than or equal to 0.5 and less than or equal to 3. In some embodiments, the aspect ratio of the substrate via hole 13 is greater than or equal to 0.2 and less than or equal to 3.2. In some embodiments, the aspect ratio of the substrate via hole 13 is greater than or equal to 0.2 and less than or equal to 2.8. In some embodiments, the aspect ratio of the substrate via hole 13 is greater than or equal to 0.2 and less than or equal to 2.6. In some embodiments, the aspect ratio of the substrate via hole 13 is greater than or equal to 0.2 and less than or equal to 2.4. In some embodiments, the aspect ratio of the substrate via hole 13 is greater than or equal to 0.2 and less than or equal to 2.2. In some embodiments, the aspect ratio of the substrate via hole 13 is greater than or equal to 0.2 and less than or equal to 2.

In some embodiments, the structure is basically is basically the same as the structure of the embodiment of FIGS. 1A and 1B, except that the depth D1 of the substrate via hole 13 is greater than or equal to 10 μm and less than or equal to 40 μm and the width of the substrate via hole 13 is greater than or equal to 5 μm and less than or equal to 50 μm when the cross-sectional view is taken along the section line, when forming the seed metal layer 20 and the backside metal layer 30, the seed metal layer 20 can be uniformly deposited on the inner surface 14 of the substrate via hole 13 and the bottom surface 12 of the semiconductor substrate 10 and the backside metal layer 30 can be uniformly deposited on the outer surface 50 of the seed metal layer 20 (including the outer surface 51 of the substrate-via-hole-bottom seed metal layer 21, the outer surface 57 of the substrate-via-hole-surrounding seed metal layer 27, and the outer surface 52 of the substrate-bottom-surface seed metal layer 22), respectively. Thereby a thickness uniformity of the seed metal layer 20 (including the substrate-via-hole-bottom seed metal layer 21, the substrate-via-hole-surrounding seed metal layer 27, and the substrate-bottom-surface seed metal layer 22) can be significantly improved, and a thickness uniformity of the backside metal layer 30 (including the substrate-via-hole-bottom backside metal layer 31, the substrate-via-hole-surrounding backside metal layer 37, and the substrate-bottom-surface backside metal layer 32) can also be significantly improved too. Since the thickness uniformity of the seed metal layer 20 and the thickness uniformity of the backside metal layer 30 are both significantly improved such that a resistance of the second circuit layout 7 (including the seed metal layer 20 and the backside metal layer 30) is significantly reduced. Thereby, the heat dissipation of the semiconductor integrated circuit 1 of the present invention can be significantly reduced such that the power consumption of the semiconductor integrated circuit 1 of the present invention can be significantly reduced. Moreover, the peeling phenomenon between the seed metal layer 20 and the semiconductor substrate 10 can be prevented and thereby avoiding damage to the reliability of the semiconductor integrated circuit 1 of the present invention.

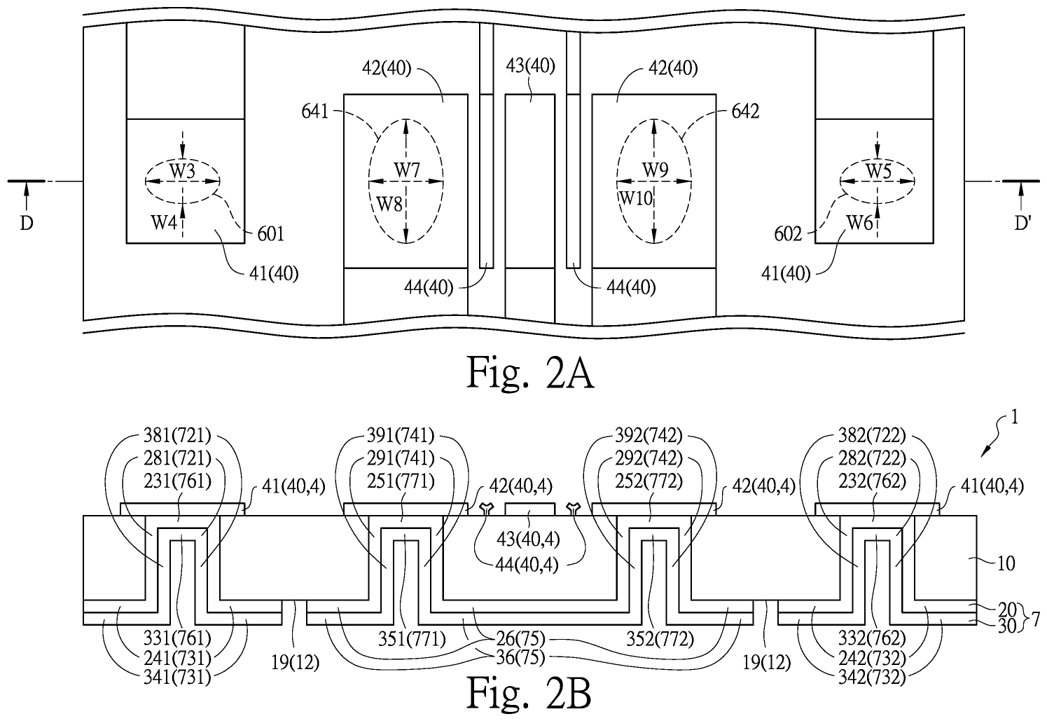

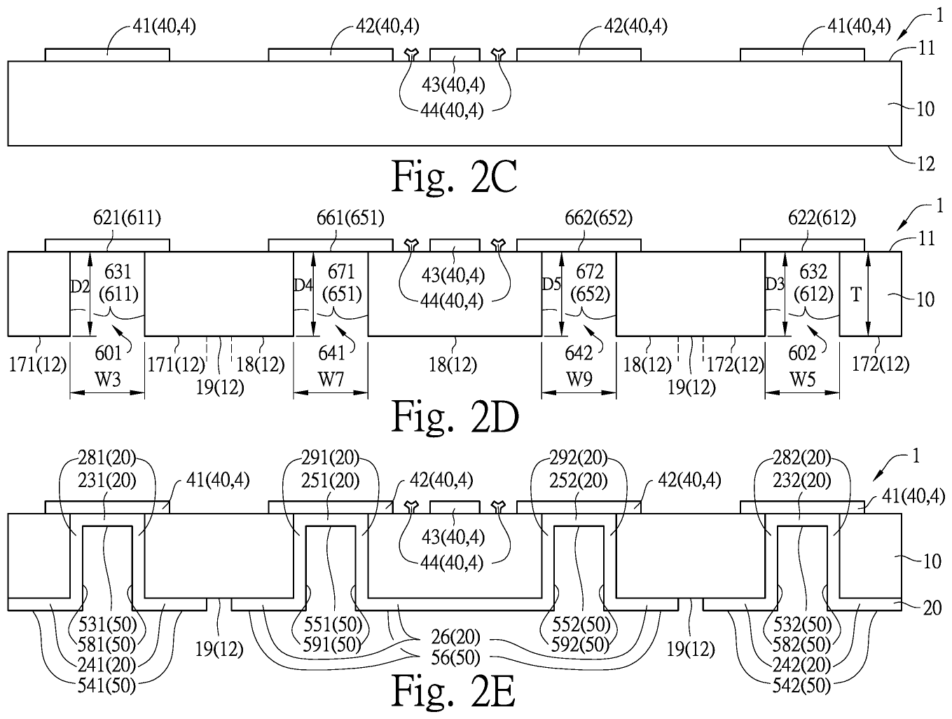

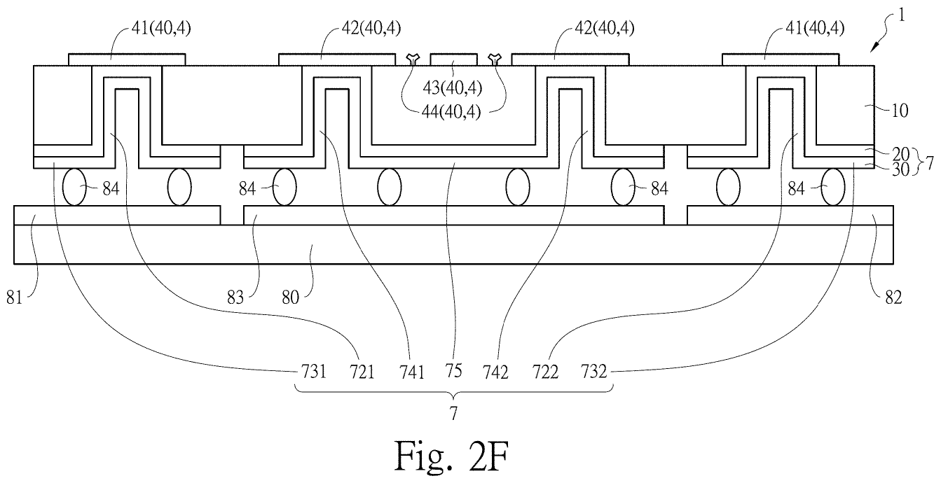

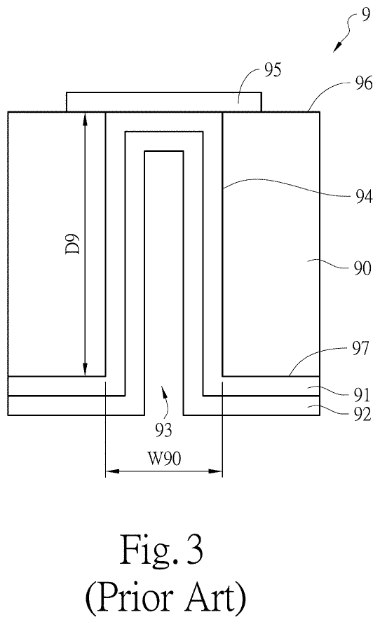

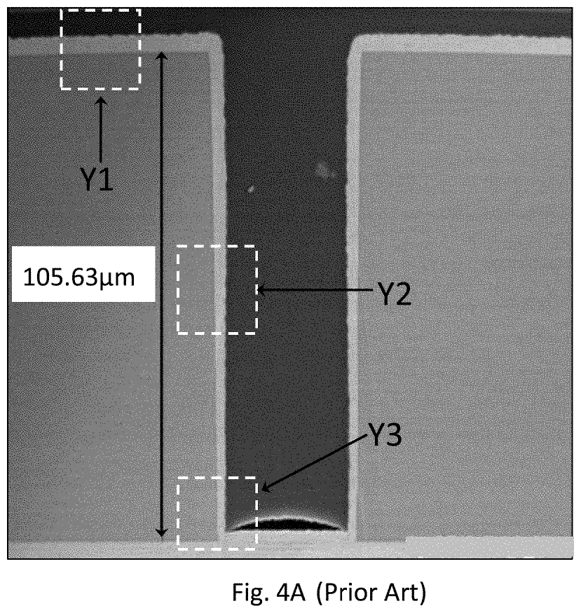

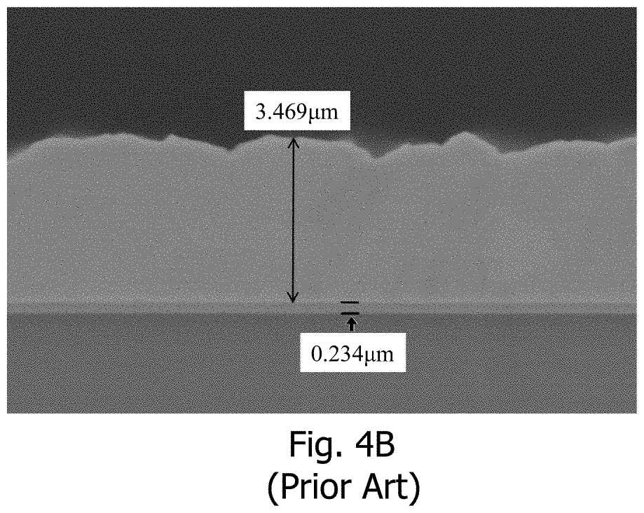

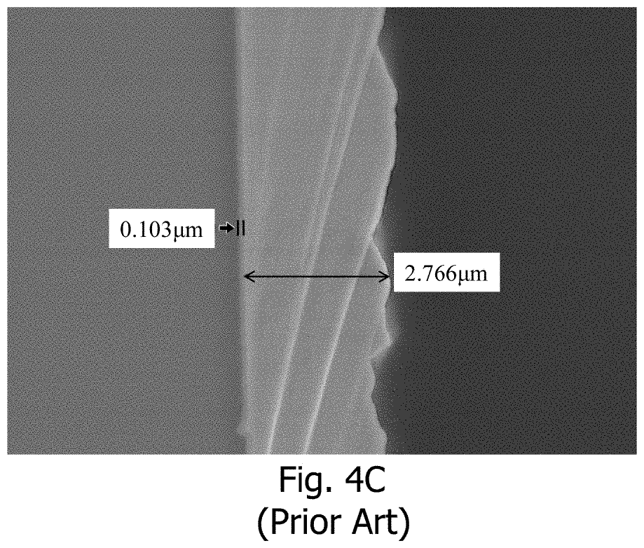

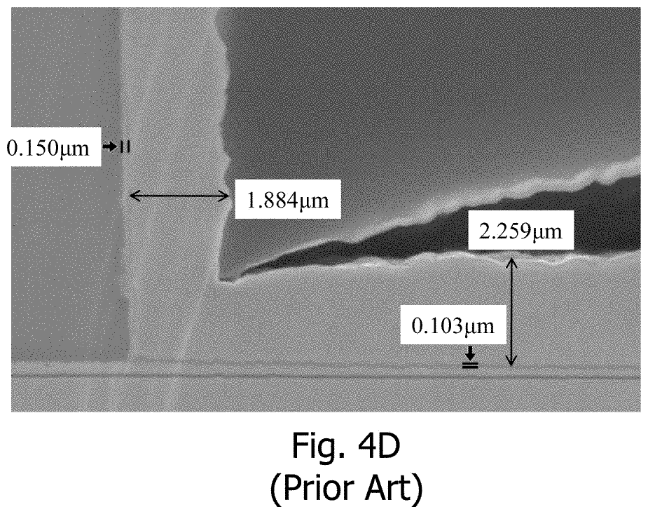

In the embodiment of FIGS. 1A and 1B, the second circuit layout 7 includes the seed metal layer 20 and the backside metal layer 30. Since the thickness uniformity of the seed metal layer 20 and the thickness uniformity of the backside metal layer 30 are both significantly improved such that the thicknesses of the substrate-via-hole-surrounding seed metal layer 27 and the substrate-via-hole-surrounding backside metal layer 37 of the second circuit layout 7 are very uniform and also such that a variation of an inductance value of the substrate-via-hole-surrounding seed metal layer 27 and the substrate-via-hole-surrounding backside metal layer 37 of the second circuit layout 7 is very small, thereby the influence on the performance and the characteristics of the semiconductor integrated circuit 1 of the present invention can be greatly reduced. Furthermore, since the variation of the inductance value of the substrate-via-hole-surrounding seed metal layer 27 and the substrate-via-hole-surrounding backside metal layer 37 of the second circuit layout 7 is very small, the substrate-via-hole-surrounding seed metal layer 27 and the substrate-via-hole-surrounding backside metal layer 37 of the second circuit layout 7 can be designed as an inductor of the semiconductor integrated circuit 1 of the present invention, such that the inductance value of the substrate-via-hole-surrounding seed metal layer 27 and the substrate-via-hole-surrounding backside metal layer 37 of the second circuit layout 7 meets the needs of the semiconductor integrated circuit 1 of the present invention for use in the semiconductor integrated circuit 1. Moreover, since the inductance value of the substrate-via-hole-surrounding seed metal layer 27 and the substrate-via-hole-surrounding backside metal layer 37 of the second circuit layout 7 is very small and also the variation of the inductance value is very small, therefore, it can meet the needs of broadband high frequency RF circuit applications. Hence, the second circuit layout 7 of the semiconductor integrated circuit 1 of the present invention includes three parts: a substrate-via-hole-bottom connection part 78, a substrate via hole inductor 70, and an electrical connection part 71. The substrate-via-hole-bottom connection part 78 includes the substrate-via-hole-bottom seed metal layer 21 and the substrate-via-hole-bottom backside metal layer 31. The substrate-via-hole-bottom connection part 78 can be used as the electrical connection between the second circuit layout 7 and the first circuit layout 4 of the semiconductor integrated circuit 1 of the present invention. The electrical connection part 71 includes the substrate-bottom-surface seed metal layer 22 and the substrate-bottom-surface backside metal layer 32. The electrical connection part 71 can be used as the electrical connection between the second circuit layout 7 of the semiconductor integrated circuit 1 of the present invention and the external electrical circuit. The substrate via hole inductor 70 includes the substrate-via-hole-surrounding seed metal layer 27 and the substrate-via-hole-surrounding backside metal layer 37. The substrate via hole inductor 70 can be designed as an inductor of the semiconductor integrated circuit 1 of the present invention such that an inductance value of the substrate via hole inductor 70 meets the needs of the semiconductor integrated circuit 1 of the present invention. In some embodiments, the semiconductor integrated circuit 1 of the present invention is an RF circuit, wherein the RF circuit includes the front-side metal layer 40 of the first circuit layout 4, some other circuit parts (not shown in FIGS. 1A and 1B) of the first circuit layout 4 formed on the top surface 11 of the semiconductor substrate 10, and the second circuit layout 7 (including the substrate-via-hole-bottom connection part 78, the substrate via hole inductor 70, and the electrical connection part 71), wherein the substrate via hole 13 is a hot via, while the substrate via hole inductor 70 can be used as a hot via inductor of the semiconductor integrated circuit 1 (RF circuit), wherein the semiconductor integrated circuit 1 of the present invention is electrically connected to one of an RF signal output terminal and an RF signal input terminal (please refer to FIG. 2F later) through the electrical connection part 71. In some other embodiments, the substrate via hole 13 is a non-hot via; while the substrate via hole inductor 70 is a non-hot via inductor, wherein the semiconductor integrated circuit 1 of the present invention is grounded or electrically connected to other electric circuit (please refer to FIG. 2F later) through the electrical connection part 71. Hence, the signal flowing through the substrate via hole inductor 70 can be a DC signal in addition to the RF signal. No matter the substrate via hole inductor 70 is a hot via inductor or a non-hot via inductor, using the substrate via hole inductor 70 as an inductor of the semiconductor integrated circuit 1 of the present invention can significantly reduce the size of the area of the semiconductor integrated circuit 1 (usually, the inductors of conventional technology are formed on the top surface of the semiconductor substrate, and the sizes of the inductors are very large, and the inductors occupy a considerable area of the semiconductor integrated circuit of conventional technology). Moreover, the inductance value of the substrate via hole inductor 70 is corresponding to a shape, the depth (D1) and the width of the substrate via hole 13, a thickness of the seed metal layer 20, and a thickness of the backside metal layer 30, hence, the circuit layout method for semiconductor integrated circuit 1 of the present invention further comprises a following step of: Step A0: designing the shape, the depth (D1) and the width of the substrate via hole 13, the thickness of the seed metal layer 20, and the thickness of the backside metal layer 30 such that the inductance value of the substrate via hole inductor 70 meets the needs of the semiconductor integrated circuit 1 of the present invention. In some embodiments, the Step A0 is executed before the Step A1; in some other embodiments, the Step A0 is executed after the Step A1; in some embodiments, the Step A0 is executed before the Step B1, wherein the Step B1 is that: etching the semiconductor substrate 10 to form the substrate via hole 13 such that the substrate via hole 13 has the shape, the depth, and the width designed in the Step A0.

In some embodiments, the inductance value of the substrate via hole inductor 70 is greater than or equal to 0.01 pH (picohenry) and less than or equal to 17.0 pH. In some embodiments, the inductance value of the substrate via hole inductor 70 is greater than or equal to 0.05 pH and less than or equal to 17.0 pH. In some embodiments, the inductance value of the substrate via hole inductor 70 is greater than or equal to 0.15 pH and less than or equal to 17.0 pH. In some embodiments, the inductance value of the substrate via hole inductor 70 is greater than or equal to 0.2 pH and less than or equal to 17.0 pH. In some embodiments, the inductance value of the substrate via hole inductor 70 is greater than or equal to 0.25 pH and less than or equal to 17.0 pH. In some embodiments, the inductance value of the substrate via hole inductor 70 is greater than or equal to 0.3 pH and less than or equal to 17.0 pH. In some embodiments, the inductance value of the substrate via hole inductor 70 is greater than or equal to 0.1 pH and less than or equal to 25.0 pH. In some embodiments, the inductance value of the substrate via hole inductor 70 is greater than or equal to 0.1 pH and less than or equal to 20.0 pH. In some embodiments, the inductance value of the substrate via hole inductor 70 is greater than or equal to 0.1 pH and less than or equal to 15.0 pH. In some embodiments, the inductance value of the substrate via hole inductor 70 is greater than or equal to 0.1 pH and less than or equal to 13.0 pH. In some embodiments, the inductance value of the substrate via hole inductor 70 is greater than or equal to 0.1 pH and less than or equal to 11.0 pH. In some embodiments, the inductance value of the substrate via hole inductor 70 is greater than or equal to 0.1 pH and less than or equal to 9.0 pH.

Please refer to FIG. 1F, which is a schematic top view of another embodiment of a semiconductor integrated circuit of the present invention. Please also refer to FIG. 1G, which is a schematic cross-sectional view taken along the section line B-B′ of the embodiment of FIG. 1F. The main structure of the embodiment of FIGS. 1F and 1G is basically the same as the structure of the embodiment of FIGS. 1A and 1B, except that it further comprises a substrate upper trench 85, wherein the front-side metal layer 40 of the first circuit layout 4 is formed on an inner surface of the substrate upper trench 85 and the top surface 11 of the semiconductor substrate 10. Please also refer to FIGS. 1H, 1I and 1J, which are schematic cross-sectional views showing steps of a circuit layout method for semiconductor integrated circuit of the present invention for fabricating the embodiment of FIGS. 1F and 1G. The steps for fabricating the embodiment of FIGS. 1F and 1G are basically the same as the steps for fabricating the embodiment of FIGS. 1A and 1B, except that, before the Step A1, the method further comprises a following step of: etching the semiconductor substrate 10 from the top surface 11 of the semiconductor substrate 10 to form the substrate upper trench 85, wherein, in the Step A1, the front-side metal layer 40 of the first circuit layout 4 is formed on the inner surface of the substrate upper trench 85 and the top surface 11 of the semiconductor substrate 10, wherein the bottom 15 of the inner surface 14 of the substrate via hole 13 is partially defined by the front-side metal layer 40 and partially defined by the semiconductor substrate 10. The width of the substrate via hole 13 is greater than a width of the substrate upper trench 85 (in some embodiments, the width of the substrate via hole 13 is equal to the width of the substrate upper trench 85). In current embodiment, the thickness T of the semiconductor substrate 10 is greater than the depth D1 of the substrate via hole 13.

Please refer to FIG. 1K, which is a schematic top view of another embodiment of a semiconductor integrated circuit of the present invention. Please also refer to FIG. 1L, which is a schematic cross-sectional view taken along the section line C-C′ of the embodiment of FIG. 1K. The main structure of the embodiment of FIGS. 1K and 1L is basically the same as the structure of the embodiment of FIGS. 1A and 1B, except that it further comprises a substrate upper trench 85, wherein the front-side metal layer 40 of the first circuit layout 4 is formed on an inner surface of the substrate upper trench 85 and the top surface 11 of the semiconductor substrate 10. Please also refer to FIGS. 1M, 1N and 10, which are schematic cross-sectional views showing steps of a circuit layout method for semiconductor integrated circuit of the present invention for fabricating the embodiment of FIGS. 1K and 1L. The steps for fabricating the embodiment of FIGS. 1K and 1L are basically the same as the steps for fabricating the embodiment of FIGS. 1A and 1B, except that, before the Step A1, the method further comprises a following step of: etching the semiconductor substrate 10 from the top surface 11 of the semiconductor substrate 10 to form the substrate upper trench 85, wherein, in the Step A1, the front-side metal layer 40 of the first circuit layout 4 is formed on the inner surface of the substrate upper trench 85 and the top surface 11 of the semiconductor substrate 10, wherein the bottom 15 of the inner surface 14 of the substrate via hole 13 is defined by the front-side metal layer 40. The width of the substrate via hole 13 is less than a width of the substrate upper trench 85 (in some embodiments, the width of the substrate via hole 13 is equal to the width of the substrate upper trench 85). In current embodiment, the thickness T of the semiconductor substrate 10 is greater than the depth D1 of the substrate via hole 13.

Please refer to FIG. 1P, which is a cross-sectional image of the scanning electron microscope of an embodiment of a semiconductor integrated circuit of the present invention. Please also refer to FIGS. 1Q, 1R and 1S, which are respectively partial enlargements of X1, X2 and X3 blocks of the embodiment of FIG. 1P of the present invention. In the embodiment of FIG. 1P of the present invention, the aspect ratio of the substrate via hole 13 is about 0.9. From FIGS. 1Q, 1R and 1S, it is very clear that the thickness of the seed metal layer 20 is distributed at 0.21 μm, 0.20 μm, 0.19 μm, and 0.21 μm; while the thickness of the backside metal layer 30 is distributed at 3.73 μm, 3.88 μm, 3.77 μm, and 3.65 μm. That is that the ratio of the thicker seed metal layer 20 and the thinner seed metal layer 20 is reduced to about 1.1; while the ratio of the thicker backside metal layer 30 and the thinner backside metal layer 30 is reduced to about 1.06. Hence, the thickness uniformity of the seed metal layer 20 and thickness uniformity of the backside metal layer 30 of the present invention can indeed be significantly improved. Please also refer to FIG. 1T, which is a comparison chart of the resistance measurement of the second circuit layout of the embodiment of FIGS. 1A and 1B of the present invention and the resistance measurement of the embodiment of conventional technology. From FIG. 1T, it is very clear that the resistance measurement of the second circuit layout of the embodiment of FIGS. 1A and 1B of the present invention is about 10.5 ohm; while the resistance measurement of conventional technology is about 21 which is about twice of the resistance measurement of the present invention. Hence, the thickness uniformity of the seed metal layer 20 and thickness uniformity of the backside metal layer 30 of the present invention can indeed be significantly improved, the resistance of the second circuit layout 7 (including the seed metal layer 20 and the backside metal layer 30) can indeed be significantly reduced. Thereby, the heat dissipation of the semiconductor integrated circuit 1 of the present invention can be significantly reduced such that the power consumption of the semiconductor integrated circuit 1 of the present invention can be significantly reduced.

Please refer to FIG. 2A, which is a schematic top view of an embodiment of a semiconductor integrated circuit of the present invention. Please also refer to FIG. 2B, which is a schematic cross-sectional view taken along the section line D-D′ of the embodiment of FIG. 2A. A semiconductor integrated circuit 1 of the present invention comprises a semiconductor substrate 10, a first circuit layout 4 and a second circuit layout 7. The first circuit layout 4 comprises a front-side metal layer 40. The front-side metal layer 40 comprises two first parts 41, two second parts 42, a third part 43 and two fourth parts 44. The second circuit layout 7 comprises a seed metal layer 20 and a backside metal layer 30. The semiconductor substrate 10 has two first substrate via holes 601, 602, two second substrate via holes 641, 642, a top surface 11 and a bottom surface 12. A circuit layout method for semiconductor integrated circuit 1 of the present invention comprises following steps of: Step A1: (please also refer to FIG. 2C, which is a schematic cross-sectional view showing a step of a circuit layout method for semiconductor integrated circuit of the present invention for fabricating the embodiment of FIGS. 2A and 2B) forming the first circuit layout 4 on the top surface 11 of the semiconductor substrate 10, wherein the first circuit layout 4 comprises the front-side metal layer 40, wherein the front-side metal layer 40 comprises two first parts 41, two second parts 42, a third part 43 and two fourth parts 44; Step B1: (please also refer to FIG. 2D, which is a schematic cross-sectional view showing another step of a circuit layout method for semiconductor integrated circuit of the present invention for fabricating the embodiment of FIGS. 2A and 2B) etching the semiconductor substrate 10 from the bottom surface 12 of the semiconductor substrate 10 to form the first substrate via holes 601, 602, and the second substrate via holes 641, 642; wherein the first substrate via hole 601 has an inner surface 611; the inner surface 611 of the first substrate via hole 601 includes a bottom 621 and a surrounding 631; the bottom 621 of the inner surface 611 of the first substrate via hole 601 is defined by one of the first parts 41 of the front-side metal layer 40; the surrounding 631 of the inner surface 611 of the first substrate via hole 601 is defined by the semiconductor substrate 10; the first substrate via hole 602 has an inner surface 612; the inner surface 612 of the first substrate via hole 602 includes a bottom 622 and a surrounding 632; the bottom 622 of the inner surface 612 of the first substrate via hole 602 is defined by the other of the first parts 41 of the front-side metal layer 40; the surrounding 632 of the inner surface 612 of the first substrate via hole 602 is defined by the semiconductor substrate 10; the second substrate via hole 641 has an inner surface 651; the inner surface 651 of the second substrate via hole 641 includes a bottom 661 and a surrounding 671; the bottom 661 of the inner surface 651 of the second substrate via hole 641 is defined by one of the second parts 42 of the front-side metal layer 40; the surrounding 671 of the inner surface 651 of the second substrate via hole 641 is defined by the semiconductor substrate 10; the second substrate via hole 642 has an inner surface 652; the inner surface 652 of the second substrate via hole 642 includes a bottom 662 and a surrounding 672; the bottom 662 of the inner surface 652 of the second substrate via hole 642 is defined by the other of the second parts 42 of the front-side metal layer 40; the surrounding 672 of the inner surface 652 of the second substrate via hole 642 is defined by the semiconductor substrate 10; wherein the semiconductor substrate 10 is made by one material selected from the group consisting of: GaAs, InP, GaN, sapphire and SiC; the semiconductor substrate 10 has a thickness T; wherein the first substrate via hole 601 has a depth D2; the first substrate via hole 602 has a depth D3; the second substrate via hole 641 has a depth D4; the second substrate via hole 642 has a depth D5; in current embodiment, T=D2=D3=D4=D5; wherein the bottom surface 12 of the semiconductor substrate 10 comprises the first areas 171, 172, a second area 18, and a separation area 19; the separation area 19 separates the first area 171 of the bottom surface 12 of the semiconductor substrate 10 from the second area 18 of the bottom surface 12 of the semiconductor substrate 10; the separation area 19 separates the first area 172 of the bottom surface 12 of the semiconductor substrate 10 from the second area 18 of the bottom surface 12 of the semiconductor substrate 10; the first area 171 of the bottom surface 12 of the semiconductor substrate 10 is not adjacent to the first area 172 of the bottom surface 12 of the semiconductor substrate 10; that is that the first area 171 of the bottom surface 12 of the semiconductor substrate 10, the first area 172 of the bottom surface 12 of the semiconductor substrate 10, and the second area 18 of the bottom surface 12 of the semiconductor substrate 10 are separated and are not connected to each other; and Step C1: forming the second circuit layout 7, wherein the Step C1 comprises following steps of: Step C11: (please also refer to FIG. 2E, which is a schematic cross-sectional view showing another step of a circuit layout method for semiconductor integrated circuit of the present invention for fabricating the embodiment of FIGS. 2A and 2B) forming the seed metal layer 20 on the inner surface 611 of the first substrate via hole 601, the inner surface 612 of the first substrate via hole 602, the inner surface 651 of the second substrate via hole 641, the inner surface 652 of the second substrate via hole 642, the first area 171 of the bottom surface 12 of the semiconductor substrate 10, the first area 172 of the bottom surface 12 of the semiconductor substrate 10, and the second area 18 of the bottom surface 12 of the semiconductor substrate 10; the seed metal layer 20 includes a first-substrate-via-hole-bottom seed metal layer 231 formed on the bottom 621 of the inner surface 611 of the first substrate via hole 601, a first-substrate-via-hole-surrounding seed metal layer 281 formed on the surrounding 631 of the inner surface 611 of the first substrate via hole 601, a first-substrate-via-hole-bottom seed metal layer 232 formed on the bottom 622 of the inner surface 612 of the first substrate via hole 602, a first-substrate-via-hole-surrounding seed metal layer 282 formed on the surrounding 632 of the inner surface 612 of the first substrate via hole 602, a second-substrate-via-hole-bottom seed metal layer 251 formed on the bottom 661 of the inner surface 651 of the second substrate via hole 641, a second-substrate-via-hole-surrounding seed metal layer 291 formed on the surrounding 671 of the inner surface 651 of the second substrate via hole 641, a second-substrate-via-hole-bottom seed metal layer 252 formed on the bottom 662 of the inner surface 652 of the second substrate via hole 642, a second-substrate-via-hole-surrounding seed metal layer 292 formed on the surrounding 672 of the inner surface 652 of the second substrate via hole 642, a first-substrate-bottom-surface seed metal layer 241 is formed on the first area 171 of the bottom surface 12 of the semiconductor substrate 10, a first-substrate-bottom-surface seed metal layer 242 is formed on the first area 172 of the bottom surface 12 of the semiconductor substrate 10, and a second-substrate-bottom-surface seed metal layer 26 formed on the second area 18 of the bottom surface 12 of the semiconductor substrate 10; wherein the first-substrate-bottom-surface seed metal layer 241, the first-substrate-bottom-surface seed metal layer 242, and the second-substrate-bottom-surface seed metal layer 26 are separated and are not connected to each other; wherein the first-substrate-via-hole-bottom seed metal layer 231 and the first-substrate-via-hole-bottom seed metal layer 232 are electrically connected to one and the other of the first parts 41 of the front-side metal layer 40, respectively; the second-substrate-via-hole-bottom seed metal layer 251 and the second-substrate-via-hole-bottom seed metal layer 252 are electrically connected to one and the other of the second parts 42 of the front-side metal layer 40, respectively; wherein the seed metal layer 20 has an outer surface 50; the outer surface 50 of the seed metal layer 20 includes an outer surface 531 of the first-substrate-via-hole-bottom seed metal layer 231, an outer surface 532 of the first-substrate-via-hole-bottom seed metal layer 232, an outer surface 581 of the first-substrate-via-hole-surrounding seed metal layer 281, an outer surface 582 of the first-substrate-via-hole-surrounding seed metal layer 282, an outer surface 551 of the second-substrate-via-hole-bottom seed metal layer 251, an outer surface 552 of the second-substrate-via-hole-bottom seed metal layer 252, an outer surface 591 of the second-substrate-via-hole-surrounding seed metal layer 291, an outer surface 592 of the second-substrate-via-hole-surrounding seed metal layer 292, an outer surface 541 of the first-substrate-bottom-surface seed metal layer 241, an outer surface 542 of the first-substrate-bottom-surface seed metal layer 242, and an outer surface 56 of the second-substrate-bottom-surface seed metal layer 26; wherein the seed metal layer 20 is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy; in some embodiments, the seed metal layer 20 is deposited on the inner surface 611 of the first substrate via hole 601, the inner surface 612 of the first substrate via hole 602, the inner surface 651 of the second substrate via hole 641, the inner surface 652 of the second substrate via hole 642, the first area 171 of the bottom surface 12 of the semiconductor substrate 10, the first area 172 of the bottom surface 12 of the semiconductor substrate 10, and the second area 18 of the bottom surface 12 of the semiconductor substrate 10 by the method of sputtering or the method of electroless plating, etc.; and Step C12: (please also refer to FIGS. 2A and 2) forming the backside metal layer 30 on the outer surface 50 of the seed metal layer 20, wherein the backside metal layer 30 includes a first-substrate-via-hole-bottom backside metal layer 331 formed on the outer surface 531 of the first-substrate-via-hole-bottom seed metal layer 231, a first-substrate-via-hole-bottom backside metal layer 332 formed on the outer surface 532 of the first-substrate-via-hole-bottom seed metal layer 232, a first-substrate-via-hole-surrounding backside metal layer 381 formed on the outer surface 581 of the first-substrate-via-hole-surrounding seed metal layer 281, a first-substrate-via-hole-surrounding backside metal layer 382 formed on the outer surface 582 of the first-substrate-via-hole-surrounding seed metal layer 282, a second-substrate-via-hole-bottom backside metal layer 351 formed on the outer surface 551 of the second-substrate-via-hole-bottom seed metal layer 251, a second-substrate-via-hole-bottom backside metal layer 352 formed on the outer surface 552 of the second-substrate-via-hole-bottom seed metal layer 252, a second-substrate-via-hole-surrounding backside metal layer 391 formed on the outer surface 591 of the second-substrate-via-hole-surrounding seed metal layer 291, a second-substrate-via-hole-surrounding backside metal layer 392 formed on the outer surface 592 of the second-substrate-via-hole-surrounding seed metal layer 292, a first-substrate-bottom-surface backside metal layer 341 formed on the outer surface 541 of the first-substrate-bottom-surface seed metal layer 241, a first-substrate-bottom-surface backside metal layer 342 formed on the outer surface 542 of the first-substrate-bottom-surface seed metal layer 242, and a second-substrate-bottom-surface backside metal layer 36 formed on the outer surface 56 of the second-substrate-bottom-surface seed metal layer 26; wherein the backside metal layer 30 is made by at least one material selected from the group consisting of: Au and Cu; in some embodiments, the backside metal layer 30 is deposited on the outer surface 50 of the seed metal layer 20 by the method of plating. The width of the first substrate via hole 601 is width=W3, when the cross-sectional view is taken along the section line D-D′, while the width of the first substrate via hole 601 is width=W4, when the cross-sectional view is taken along the section line perpendicular to D-D′. The width of the first substrate via hole 602 is width=W5, when the cross-sectional view is taken along the section line D-D′, while the width of the first substrate via hole 602 is width=W6, when the cross-sectional view is taken along the section line perpendicular to D-D′. The width of the second substrate via hole 641 is width=W7, when the cross-sectional view is taken along the section line D-D′, while the width of the second substrate via hole 641 is width=W8, when the cross-sectional view is taken along the section line perpendicular to D-D′. The width of the second substrate via hole 642 is width=W9, when the cross-sectional view is taken along the section line D-D′, while the width of the second substrate via hole 642 is width=W10, when the cross-sectional view is taken along the section line perpendicular to D-D′. Similar to the embodiment of FIGS. 1A and 1B, when the cross-sectional view is taken along the section line, the aspect ratio of any of the first substrate via hole 601, first substrate via hole 602, the second substrate via hole 641, and the second substrate via hole 642 is greater than or equal to 0.2 and less than or equal to 3 (i.e. 0.2≤the aspect ratio≤3), the aspect ratio of any of the first substrate via hole 601, first substrate via hole 602, the second substrate via hole 641, and the second substrate via hole 642 is small enough, so that when forming the seed metal layer 20 and the backside metal layer 30, the seed metal layer 20 can be uniformly deposited on the inner surface 611 of the first substrate via hole 601, the inner surface 612 of the first substrate via hole 602, the inner surface 651 of the second substrate via hole 641, the inner surface 652 of the second substrate via hole 642, the first area 171 of the bottom surface 12 of the semiconductor substrate 10, the first area 172 of the bottom surface 12 of the semiconductor substrate 10, and the second area 18 of the bottom surface 12 of the semiconductor substrate 10, and the backside metal layer 30 can be uniformly deposited on the outer surface 50 of the seed metal layer 20 (including the outer surface 531 of the first-substrate-via-hole-bottom seed metal layer 231, the outer surface 581 of the first-substrate-via-hole-surrounding seed metal layer 281, the outer surface 532 of the first-substrate-via-hole-bottom seed metal layer 232, the outer surface 582 of the first-substrate-via-hole-surrounding seed metal layer 282, the outer surface 551 of the second-substrate-via-hole-bottom seed metal layer 251, the outer surface 591 of the second-substrate-via-hole-surrounding seed metal layer 291, the outer surface 552 of the second-substrate-via-hole-bottom seed metal layer 252, the outer surface 592 of the second-substrate-via-hole-surrounding seed metal layer 292, the outer surface 541 of the first-substrate-bottom-surface seed metal layer 241, the outer surface 542 of the first-substrate-bottom-surface seed metal layer 242, and the outer surface 56 of the second-substrate-bottom-surface seed metal layer 26), respectively. Thereby a thickness uniformity of the seed metal layer 20 can be significantly improved, and a thickness uniformity of the backside metal layer 30 can also be significantly improved. Since the thickness uniformity of the seed metal layer 20 and the thickness uniformity of the backside metal layer 30 are both significantly improved such that a resistance of the second circuit layout 7 (including the seed metal layer 20 and the backside metal layer 30) is significantly reduced. Thereby, the heat dissipation of the semiconductor integrated circuit 1 of the present invention can be significantly reduced such that the power consumption of the semiconductor integrated circuit 1 of the present invention can be significantly reduced. Moreover, the peeling phenomenon between the seed metal layer 20 and the semiconductor substrate 10 can be prevented and thereby avoiding damage to the reliability of the semiconductor integrated circuit 1 of the present invention.

In some preferable embodiments, the depth D2 of the first substrate via hole 601 and the depth D3 of the first substrate via hole 602 are greater than or equal to 10 μm and less than or equal to 40 μm. In some embodiments, the depth D2 of the first substrate via hole 601 and the depth D3 of the first substrate via hole 602 are greater than or equal to 5 μm and less than or equal to 40 μm. In some embodiments, the depth D2 of the first substrate via hole 601 and the depth D3 of the first substrate via hole 602 are greater than or equal to 8 μm and less than or equal to 40 μm. In some embodiments, the depth D2 of the first substrate via hole 601 and the depth D3 of the first substrate via hole 602 are greater than or equal to 13 μm and less than or equal to 40 μm. In some embodiments, the depth D2 of the first substrate via hole 601 and the depth D3 of the first substrate via hole 602 are greater than or equal to 15 μm and less than or equal to 40 μm. In some embodiments, the depth D2 of the first substrate via hole 601 and the depth D3 of the first substrate via hole 602 are greater than or equal to 10 μm and less than or equal to 35 μm. In some embodiments, the depth D2 of the first substrate via hole 601 and the depth D3 of the first substrate via hole 602 are greater than or equal to 10 μm and less than or equal to 25 μm. In some embodiments, the depth D2 of the first substrate via hole 601 and the depth D3 of the first substrate via hole 602 are greater than or equal to 10 μm and less than or equal to 20 μm. In some embodiments, the depth D2 of the first substrate via hole 601 and the depth D3 of the first substrate via hole 602 are greater than or equal to 10 μm and less than or equal to 45 μm. In some embodiments, the depth D2 of the first substrate via hole 601 and the depth D3 of the first substrate via hole 602 are greater than or equal to 10 μm and less than or equal to 50 μm.

In some preferable embodiments, the depth D4 of the second substrate via hole 641 and the depth D5 of the second substrate via hole 642 are greater than or equal to 10 μm and less than or equal to 40 μm. In some embodiments, the depth D4 of the second substrate via hole 641 and the depth D5 of the second substrate via hole 642 are greater than or equal to 5 μm and less than or equal to 40 μm. In some embodiments, the depth D4 of the second substrate via hole 641 and the depth D5 of the second substrate via hole 642 are greater than or equal to 8 μm and less than or equal to 40 μm. In some embodiments, the depth D4 of the second substrate via hole 641 and the depth D5 of the second substrate via hole 642 are greater than or equal to 13 μm and less than or equal to 40 μm. In some embodiments, the depth D4 of the second substrate via hole 641 and the depth D5 of the second substrate via hole 642 are greater than or equal to 15 μm and less than or equal to 40 μm. In some embodiments, the depth D4 of the second substrate via hole 641 and the depth D5 of the second substrate via hole 642 are greater than or equal to 10 μm and less than or equal to 35 μm. In some embodiments, the depth D4 of the second substrate via hole 641 and the depth D5 of the second substrate via hole 642 are greater than or equal to 10 μm and less than or equal to 25 μm. In some embodiments, the depth D4 of the second substrate via hole 641 and the depth D5 of the second substrate via hole 642 are greater than or equal to 10 μm and less than or equal to 20 μm. In some embodiments, the depth D4 of the second substrate via hole 641 and the depth D5 of the second substrate via hole 642 are greater than or equal to 10 μm and less than or equal to 45 μm. In some embodiments, the depth D4 of the second substrate via hole 641 and the depth D5 of the second substrate via hole 642 are greater than or equal to 10 μm and less than or equal to 50 μm.

In some preferable embodiments, the width of the first substrate via hole 601 and the width of the first substrate via hole 602 are greater than or equal to 5 μm and less than or equal to 50 μm. In some embodiments, the width of the first substrate via hole 601 and the width of the first substrate via hole 602 are greater than or equal to 5 μm and less than or equal to 45 μm. In some embodiments, the width of the first substrate via hole 601 and the width of the first substrate via hole 602 are greater than or equal to 5 μm and less than or equal to 40 μm. In some embodiments, the width of the first substrate via hole 601 and the width of the first substrate via hole 602 are greater than or equal to 5 μm and less than or equal to 35 μm. In some embodiments, the width of the first substrate via hole 601 and the width of the first substrate via hole 602 are greater than or equal to 5 μm and less than or equal to 30 μm. In some embodiments, the width of the first substrate via hole 601 and the width of the first substrate via hole 602 are greater than or equal to 5 μm and less than or equal to 25 μm. In some embodiments, the width of the first substrate via hole 601 and the width of the first substrate via hole 602 are greater than or equal to 8 μm and less than or equal to 50 μm. In some embodiments, the width of the first substrate via hole 601 and the width of the first substrate via hole 602 are greater than or equal to 10 μm and less than or equal to 50 μm. In some embodiments, the width of the first substrate via hole 601 and the width of the first substrate via hole 602 are greater than or equal to 13 μm and less than or equal to 50 μm. In some embodiments, the width of the first substrate via hole 601 and the width of the first substrate via hole 602 are greater than or equal to 15 μm and less than or equal to 50 μm. In some embodiments, the width of the first substrate via hole 601 and the width of the first substrate via hole 602 are greater than or equal to 20 μm and less than or equal to 50 μm. In some embodiments, the width of the first substrate via hole 601 and the width of the first substrate via hole 602 are greater than or equal to 25 μm and less than or equal to 50 μm. In some embodiments, the width of the first substrate via hole 601 and the width of the first substrate via hole 602 are greater than or equal to 5 μm and less than or equal to 55 μm. In some embodiments, the width of the first substrate via hole 601 and the width of the first substrate via hole 602 are greater than or equal to 5 μm and less than or equal to 60 μm.

In some preferable embodiments, the width of the second substrate via hole 641 and the width of the second substrate via hole 642 are greater than or equal to 5 μm and less than or equal to 50 μm. In some embodiments, the width of the second substrate via hole 641 and the width of the second substrate via hole 642 are greater than or equal to 5 μm and less than or equal to 45 μm. In some embodiments, the width of the second substrate via hole 641 and the width of the second substrate via hole 642 are greater than or equal to 5 μm and less than or equal to 40 μm. In some embodiments, the width of the second substrate via hole 641 and the width of the second substrate via hole 642 are greater than or equal to 5 μm and less than or equal to 35 μm. In some embodiments, the width of the second substrate via hole 641 and the width of the second substrate via hole 642 are greater than or equal to 5 μm and less than or equal to 30 μm. In some embodiments, the width of the second substrate via hole 641 and the width of the second substrate via hole 642 are greater than or equal to 5 μm and less than or equal to 25 μm. In some embodiments, the width of the second substrate via hole 641 and the width of the second substrate via hole 642 are greater than or equal to 8 μm and less than or equal to 50 μm. In some embodiments, the width of the second substrate via hole 641 and the width of the second substrate via hole 642 are greater than or equal to 10 μm and less than or equal to 50 μm. In some embodiments, the width of the second substrate via hole 641 and the width of the second substrate via hole 642 are greater than or equal to 13 μm and less than or equal to 50 μm. In some embodiments, the width of the second substrate via hole 641 and the width of the second substrate via hole 642 are greater than or equal to 15 μm and less than or equal to 50 μm. In some embodiments, the width of the second substrate via hole 641 and the width of the second substrate via hole 642 are greater than or equal to 20 μm and less than or equal to 50 μm. In some embodiments, the width of the second substrate via hole 641 and the width of the second substrate via hole 642 are greater than or equal to 25 μm and less than or equal to 50 μm. In some embodiments, the width of the second substrate via hole 641 and the width of the second substrate via hole 642 are greater than or equal to 5 μm and less than or equal to 55 μm. In some embodiments, the width of the second substrate via hole 641 and the width of the second substrate via hole 642 are greater than or equal to 5 μm and less than or equal to 60 μm.

In some embodiments, the aspect ratio of the first substrate via hole 601 and the aspect ratio of the first substrate via hole 602 are greater than or equal to 0.1 and less than or equal to 3. In some embodiments, the aspect ratio of the first substrate via hole 601 and the aspect ratio of the first substrate via hole 602 are greater than or equal to 0.3 and less than or equal to 3. In some embodiments, the aspect ratio of the first substrate via hole 601 and the aspect ratio of the first substrate via hole 602 are greater than or equal to 0.4 and less than or equal to 3. In some embodiments, the aspect ratio of the first substrate via hole 601 and the aspect ratio of the first substrate via hole 602 are greater than or equal to 0.5 and less than or equal to 3. In some embodiments, the aspect ratio of the first substrate via hole 601 and the aspect ratio of the first substrate via hole 602 are greater than or equal to 0.2 and less than or equal to 3.2. In some embodiments, the aspect ratio of the first substrate via hole 601 and the aspect ratio of the first substrate via hole 602 are greater than or equal to 0.2 and less than or equal to 2.8. In some embodiments, the aspect ratio of the first substrate via hole 601 and the aspect ratio of the first substrate via hole 602 are greater than or equal to 0.2 and less than or equal to 2.6. In some embodiments, the aspect ratio of the first substrate via hole 601 and the aspect ratio of the first substrate via hole 602 are greater than or equal to 0.2 and less than or equal to 2.4. In some embodiments, the aspect ratio of the first substrate via hole 601 and the aspect ratio of the first substrate via hole 602 are greater than or equal to 0.2 and less than or equal to 2.2. In some embodiments, the aspect ratio of the first substrate via hole 601 and the aspect ratio of the first substrate via hole 602 are greater than or equal to 0.2 and less than or equal to 2.

In some embodiments, the aspect ratio of the second substrate via hole 641 and the aspect ratio of the second substrate via hole 642 are greater than or equal to 0.1 and less than or equal to 3. In some embodiments, the aspect ratio of the second substrate via hole 641 and the aspect ratio of the second substrate via hole 642 are greater than or equal to 0.3 and less than or equal to 3. In some embodiments, the aspect ratio of the second substrate via hole 641 and the aspect ratio of the second substrate via hole 642 are greater than or equal to 0.4 and less than or equal to 3. In some embodiments, the aspect ratio of the second substrate via hole 641 and the aspect ratio of the second substrate via hole 642 are greater than or equal to 0.5 and less than or equal to 3. In some embodiments, the aspect ratio of the second substrate via hole 641 and the aspect ratio of the second substrate via hole 642 are greater than or equal to 0.2 and less than or equal to 3.2. In some embodiments, the aspect ratio of the second substrate via hole 641 and the aspect ratio of the second substrate via hole 642 are greater than or equal to 0.2 and less than or equal to 2.8. In some embodiments, the aspect ratio of the second substrate via hole 641 and the aspect ratio of the second substrate via hole 642 are greater than or equal to 0.2 and less than or equal to 2.6. In some embodiments, the aspect ratio of the second substrate via hole 641 and the aspect ratio of the second substrate via hole 642 are greater than or equal to 0.2 and less than or equal to 2.4. In some embodiments, the aspect ratio of the second substrate via hole 641 and the aspect ratio of the second substrate via hole 642 are greater than or equal to 0.2 and less than or equal to 2.2. In some embodiments, the aspect ratio of the second substrate via hole 641 and the aspect ratio of the second substrate via hole 642 are greater than or equal to 0.2 and less than or equal to 2.

In some embodiments, the structure is basically the same as the structure of the embodiment of FIGS. 2A and 2B, except that the depth D2 of the first substrate via hole 601, the depth D3 of the first substrate via hole 602, the depth D4 of the second substrate via hole 641, and the depth D5 of the second substrate via hole 642 are all greater than or equal to 10 μm and less than or equal to 40 μm and the width of the first substrate via hole 601, the width of the first substrate via hole 602, the width of the second substrate via hole 641, and the width of the second substrate via hole 642 are all greater than or equal to 5 μm and less than or equal to 50 μm when the cross-sectional view is taken along the section line. When forming the seed metal layer 20 and the backside metal layer 30, the seed metal layer 20 can be uniformly deposited on the inner surface 611 of the first substrate via hole 601, the inner surface 612 of the first substrate via hole 602, the inner surface 651 of the second substrate via hole 641, the inner surface 652 of the second substrate via hole 642, the first area 171 of the bottom surface 12 of the semiconductor substrate 10, the first area 172 of the bottom surface 12 of the semiconductor substrate 10, and the second area 18 of the bottom surface 12 of the semiconductor substrate 10, and the backside metal layer 30 can be uniformly deposited on the outer surface 50 of the seed metal layer 20 (including the outer surface 531 of the first-substrate-via-hole-bottom seed metal layer 231, the outer surface 581 of the first-substrate-via-hole-surrounding seed metal layer 281, the outer surface 532 of the first-substrate-via-hole-bottom seed metal layer 232, the outer surface 582 of the first-substrate-via-hole-surrounding seed metal layer 282, the outer surface 551 of the second-substrate-via-hole-bottom seed metal layer 251, the outer surface 591 of the second-substrate-via-hole-surrounding seed metal layer 291, the outer surface 552 of the second-substrate-via-hole-bottom seed metal layer 252, the outer surface 592 of the second-substrate-via-hole-surrounding seed metal layer 292, the outer surface 541 of the first-substrate-bottom-surface seed metal layer 241, the outer surface 542 of the first-substrate-bottom-surface seed metal layer 242, and the outer surface 56 of the second-substrate-bottom-surface seed metal layer 26), respectively. Thereby a thickness uniformity of the seed metal layer 20 can be significantly improved, and a thickness uniformity of the backside metal layer 30 can also be significantly improved. Since the thickness uniformity of the seed metal layer 20 and the thickness uniformity of the backside metal layer 30 are both significantly improved such that a resistance of the second circuit layout 7 (including the seed metal layer 20 and the backside metal layer 30) is significantly reduced. Thereby, the heat dissipation of the semiconductor integrated circuit 1 of the present invention can be significantly reduced such that the power consumption of the semiconductor integrated circuit 1 of the present invention can be significantly reduced. Moreover, the peeling phenomenon between the seed metal layer 20 and the semiconductor substrate 10 can be prevented and thereby avoiding damage to the reliability of the semiconductor integrated circuit 1 of the present invention.

In the embodiment of FIGS. 2A and 2B, the second parts 42, the third part 43 and the fourth parts 44 of the front-side metal layer 40 are a source electrode, a drain electrode and a gate electrode of a field effect transistor, respectively. In the embodiment of FIGS. 2A and 2B, the second circuit layout 7 includes the seed metal layer 20 and the backside metal layer 30. Since the thickness uniformity of the seed metal layer 20 and the thickness uniformity of the backside metal layer 30 are both significantly improved such that the first-substrate-via-hole-surrounding seed metal layer 281, the first-substrate-via-hole-surrounding backside metal layer 381, the first-substrate-via-hole-surrounding seed metal layer 282, the first-substrate-via-hole-surrounding backside metal layer 382, the second-substrate-via-hole-surrounding seed metal layer 291, the second-substrate-via-hole-surrounding backside metal layer 391, the second-substrate-via-hole-surrounding seed metal layer 292, and the second-substrate-via-hole-surrounding backside metal layer 392 of the second circuit layout 7 are all very uniform, and such that a variation of an inductance value of the first-substrate-via-hole-surrounding seed metal layer 281 and the first-substrate-via-hole-surrounding backside metal layer 381, a variation of an inductance value of the first-substrate-via-hole-surrounding seed metal layer 282 and the first-substrate-via-hole-surrounding backside metal layer 382, a variation of an inductance value of the second-substrate-via-hole-surrounding seed metal layer 291 and the second-substrate-via-hole-surrounding backside metal layer 391, and a variation of an inductance value of the second-substrate-via-hole-surrounding seed metal layer 292 and the second-substrate-via-hole-surrounding backside metal layer 392 of the second circuit layout 7 are all very small, thereby the influence on the performance and the characteristics of the semiconductor integrated circuit 1 of the present invention can be greatly reduced. Furthermore, since the variation of the inductance value of the first-substrate-via-hole-surrounding seed metal layer 281 and the first-substrate-via-hole-surrounding backside metal layer 381, the variation of the inductance value of the first-substrate-via-hole-surrounding seed metal layer 282 and the first-substrate-via-hole-surrounding backside metal layer 382, the variation of the inductance value of the second-substrate-via-hole-surrounding seed metal layer 291 and the second-substrate-via-hole-surrounding backside metal layer 391, and the variation of the inductance value of the second-substrate-via-hole-surrounding seed metal layer 292 and the second-substrate-via-hole-surrounding backside metal layer 392 of the second circuit layout 7 are all very small, the first-substrate-via-hole-surrounding seed metal layer 281 and the first-substrate-via-hole-surrounding backside metal layer 381, the first-substrate-via-hole-surrounding seed metal layer 282 and the first-substrate-via-hole-surrounding backside metal layer 382, the second-substrate-via-hole-surrounding seed metal layer 291 and the second-substrate-via-hole-surrounding backside metal layer 391, and the second-substrate-via-hole-surrounding seed metal layer 292 and the second-substrate-via-hole-surrounding backside metal layer 392 of the second circuit layout 7 can, respectively, be designed as the inductors of the semiconductor integrated circuit 1 of the present invention, such that the inductance value of the first-substrate-via-hole-surrounding seed metal layer 281 and the first-substrate-via-hole-surrounding backside metal layer 381, the inductance value of the first-substrate-via-hole-surrounding seed metal layer 282 and the first-substrate-via-hole-surrounding backside metal layer 382, the inductance value of the second-substrate-via-hole-surrounding seed metal layer 291 and the second-substrate-via-hole-surrounding backside metal layer 391, and the inductance value of the second-substrate-via-hole-surrounding seed metal layer 292 and the second-substrate-via-hole-surrounding backside metal layer 392 of the second circuit layout 7 meet the needs of the semiconductor integrated circuit 1 of the present invention for use in the semiconductor integrated circuit 1. Moreover, since the inductance value of the first-substrate-via-hole-surrounding seed metal layer 281 and the first-substrate-via-hole-surrounding backside metal layer 381, the inductance value of the first-substrate-via-hole-surrounding seed metal layer 282 and the first-substrate-via-hole-surrounding backside metal layer 382, the inductance value of the second-substrate-via-hole-surrounding seed metal layer 291 and the second-substrate-via-hole-surrounding backside metal layer 391, and the inductance value of the second-substrate-via-hole-surrounding seed metal layer 292 and the second-substrate-via-hole-surrounding backside metal layer 392 of the second circuit layout 7 are very small and also the variation of the inductance values are very small, therefore, the inductors can meet the needs of broadband high frequency RF circuit applications. Hence, the second circuit layout 7 of the semiconductor integrated circuit 1 of the present invention includes following parts of: a first-substrate-via-hole-bottom connection part 761, a first substrate via hole inductor 721, a first electrical connection part 731, a first-substrate-via-hole-bottom connection part 762, a first substrate via hole inductor 722, a first electrical connection part 732, a second-substrate-via-hole-bottom connection part 771, a second substrate via hole inductor 741, a second-substrate-via-hole-bottom connection part 772, a second substrate via hole inductor 742, and a second electrical connection part 75. The first-substrate-via-hole-bottom connection part 761 includes the first-substrate-via-hole-bottom seed metal layer 231 and the first-substrate-via-hole-bottom backside metal layer 331. The first substrate via hole inductor 721 includes the first-substrate-via-hole-surrounding seed metal layer 281 and the first-substrate-via-hole-surrounding backside metal layer 381. The first electrical connection part 731 includes the first-substrate-bottom-surface seed metal layer 241 and the first-substrate-bottom-surface backside metal layer 341. The first-substrate-via-hole-bottom connection part 762 includes the first-substrate-via-hole-bottom seed metal layer 232 and the first-substrate-via-hole-bottom backside metal layer 332. The first substrate via hole inductor 722 includes the first-substrate-via-hole-surrounding seed metal layer 282 and the first-substrate-via-hole-surrounding backside metal layer 382. The first electrical connection part 732 includes the first-substrate-bottom-surface seed metal layer 242 and the first-substrate-bottom-surface backside metal layer 342. The second-substrate-via-hole-bottom connection part 771 includes the second-substrate-via-hole-bottom seed metal layer 251 and the second-substrate-via-hole-bottom backside metal layer 351. The second substrate via hole inductor 741 includes the second-substrate-via-hole-surrounding seed metal layer 291 and the second-substrate-via-hole-surrounding backside metal layer 391. The second-substrate-via-hole-bottom connection part 772 includes the second-substrate-via-hole-bottom seed metal layer 252 and the second-substrate-via-hole-bottom backside metal layer 352. The second substrate via hole inductor 742 includes the second-substrate-via-hole-surrounding seed metal layer 292 and the second-substrate-via-hole-surrounding backside metal layer 392. The second electrical connection part 75 includes the second-substrate-bottom-surface seed metal layer 26 and the second-substrate-bottom-surface backside metal layer 36. The first-substrate-via-hole-bottom connection part 761 and the first-substrate-via-hole-bottom connection part 762 of the second circuit layout 7 are electrically connected to one and the other of the two first parts 41 of the front-side metal layer 40 of the first circuit layout 4, respectively. The second-substrate-via-hole-bottom connection part 771 and the second-substrate-via-hole-bottom connection part 772 of the second circuit layout 7 are electrically connected to one and the other of the two second parts 42 of the front-side metal layer 40 of the first circuit layout 4, respectively. The first substrate via hole inductor 721, the first substrate via hole inductor 722, the second substrate via hole inductor 741, and the second substrate via hole inductor 742 can be designed as the inductors of the semiconductor integrated circuit 1 of the present invention such that the inductance value of the first substrate via hole inductor 721, the inductance value of the first substrate via hole inductor 722, the inductance value of the second substrate via hole inductor 741, and the inductance value of the second substrate via hole inductor 742, respectively, meet the needs of the semiconductor integrated circuit 1 of the present invention. Please also refer to FIG. 2F, which is a schematic cross-sectional view of a application of the embodiment of FIGS. 2A and 2B of the present invention. The main structure of the embodiment of FIG. 2F is basically the same as the structure of the embodiment of FIGS. 2A and 2B, except that it further comprises a carrier board 80, an RF signal input terminal 81, an RF signal output terminal 82, a connection terminal 83, and a plurality of metal bumps 84. The RF signal input terminal 81, the RF signal output terminal 82, and the connection terminal 83 are formed on the carrier board 80, wherein the RF signal input terminal 81, the RF signal output terminal 82, and the connection terminal 83 are separated and are not connected to each other. The plurality of metal bumps 84 are formed on the RF signal input terminal 81, the RF signal output terminal 82, and the connection terminal 83, respectively. In current embodiment, the semiconductor integrated circuit 1 (which has the same as the structure of the embodiment of FIGS. 2A and 2B) of the present invention is an RF circuit, wherein the RF circuit includes the front-side metal layer 40 of the first circuit layout 4, some other circuit parts (not shown in FIGS. 2A and 2B) of the first circuit layout 4 formed on the top surface 11 of the semiconductor substrate 10, and the second circuit layout 7. The first substrate via hole 601 and the first substrate via hole 602 are hot vias, wherein the first substrate via hole inductor 721 and the first substrate via hole inductor 722 are hot via inductors of the semiconductor integrated circuit 1 (RF circuit). The semiconductor integrated circuit 1 of present invention is electrically connected to the RF signal input terminal 81 through the metal bumps 84 and the first electrical connection part 731. The semiconductor integrated circuit 1 of present invention is electrically connected to the RF signal output terminal 82 through the metal bumps 84 and the first electrical connection part 732. The second substrate via hole 641 and the second substrate via hole 642 are non-hot vias, wherein the second substrate via hole inductor 741 and the second substrate via hole inductor 742 are non-hot via inductors of the semiconductor integrated circuit 1. The semiconductor integrated circuit 1 of present invention is electrically connected to the connection terminal 83 through the metal bumps 84 and the second electrical connection part 75, wherein the connection terminal 83 can be grounded. In some other embodiments, the connection terminal 83 can be connected to other part of the semiconductor integrated circuit; for example, connected to a gate electrode of another transistor (not shown in FIG. 2F). In some other embodiments, the second substrate via hole 641 and the second substrate via hole 642 can be hot vias, wherein the second substrate via hole inductor 741 and the second substrate via hole inductor 742 can be hot via inductors of the semiconductor integrated circuit 1. Therefore, the signal flowing through the second substrate via hole inductor 741 and the second substrate via hole inductor 742 can be a DC signal or an RF signal. The first electrical connection part 731, the first electrical connection part 732, and the second electrical connection part 75 can be used as the electrical connection between the semiconductor integrated circuit 1 of the present invention and the external electrical circuit. No matter the hot via inductors (the first substrate via hole inductor 721 and the first substrate via hole inductor 722) or the non-hot via inductors (the second substrate via hole inductor 741 and the second substrate via hole inductor 742), using the first substrate via hole inductor 721, the first substrate via hole inductor 722, the second substrate via hole inductor 741, and the second substrate via hole inductor 742, respectively, as the inductors of the semiconductor integrated circuit 1 of the present invention can significantly reduce the area of the semiconductor integrated circuit 1 (the inductors of conventional technology are formed on the top surface of the semiconductor substrate, and the sizes of the inductors are very large, and the inductors occupy a considerable area of the semiconductor integrated circuit of conventional technology). Moreover, the inductance values of the first substrate via hole inductor 721, the first substrate via hole inductor 722, the second substrate via hole inductor 741, and the second substrate via hole inductor 742 are corresponding to a thickness of the seed metal layer 20, a thickness of the backside metal layer 30, and the shapes, the depths and the widths of the first substrate via hole 601, the first substrate via hole 602, the second substrate via hole 641, and the second substrate via hole 642, respectively, hence, the circuit layout method for semiconductor integrated circuit 1 of the present invention further comprises a following step of: Step A0: designing the thickness of the seed metal layer 20, the thickness of the backside metal layer 30, and the shapes, the depths and the widths of the first substrate via hole 601, the first substrate via hole 602, the second substrate via hole 641, and the second substrate via hole 642, respectively, such that the inductance values of the first substrate via hole inductor 721, the first substrate via hole inductor 722, the second substrate via hole inductor 741, and the second substrate via hole inductor 742 meet the needs of the semiconductor integrated circuit 1 of the present invention. In some embodiments, the Step A0 is executed before the Step A1; in some other embodiments, the Step A0 is executed after the Step A1; in some embodiments, the Step A0 is executed before the Step B1, wherein the Step B1 is that: etching the semiconductor substrate 10 to form the first substrate via hole 601, the first substrate via hole 602, the second substrate via hole 641, and the second substrate via hole 642, respectively, such that the first substrate via hole 601, the first substrate via hole 602, the second substrate via hole 641, and the second substrate via hole 642, respectively, has the shapes, the depths, and the widths designed in the Step A0.

In some embodiments, the inductance values of the first substrate via hole inductor 721 and the first substrate via hole inductor 722 are greater than or equal to 0.01 pH and less than or equal to 17.0 pH, respectively. In some embodiments, the inductance values of the first substrate via hole inductor 721 and the first substrate via hole inductor 722 are greater than or equal to 0.05 pH and less than or equal to 17.0 pH, respectively. In some embodiments, the inductance values of the first substrate via hole inductor 721 and the first substrate via hole inductor 722 are greater than or equal to 0.15 pH and less than or equal to 17.0 pH, respectively. In some embodiments, the inductance values of the first substrate via hole inductor 721 and the first substrate via hole inductor 722 are greater than or equal to 0.2 pH and less than or equal to 17.0 pH, respectively. In some embodiments, the inductance values of the first substrate via hole inductor 721 and the first substrate via hole inductor 722 are greater than or equal to 0.25 pH and less than or equal to 17.0 pH, respectively. In some embodiments, the inductance values of the first substrate via hole inductor 721 and the first substrate via hole inductor 722 are greater than or equal to 0.3 pH and less than or equal to 17.0 pH, respectively. In some embodiments, the inductance values of the first substrate via hole inductor 721 and the first substrate via hole inductor 722 are greater than or equal to 0.1 pH and less than or equal to 25.0 pH, respectively. In some embodiments, the inductance values of the first substrate via hole inductor 721 and the first substrate via hole inductor 722 are greater than or equal to 0.1 pH and less than or equal to 20.0 pH, respectively. In some embodiments, the inductance values of the first substrate via hole inductor 721 and the first substrate via hole inductor 722 are greater than or equal to 0.1 pH and less than or equal to 15.0 pH, respectively. In some embodiments, the inductance values of the first substrate via hole inductor 721 and the first substrate via hole inductor 722 are greater than or equal to 0.1 pH and less than or equal to 13.0 pH, respectively. In some embodiments, the inductance values of the first substrate via hole inductor 721 and the first substrate via hole inductor 722 are greater than or equal to 0.1 pH and less than or equal to 11.0 pH, respectively. In some embodiments, the inductance values of the first substrate via hole inductor 721 and the first substrate via hole inductor 722 are greater than or equal to 0.1 pH and less than or equal to 9.0 pH, respectively.

In some embodiments, the inductance values of the second substrate via hole inductor 741 and the second substrate via hole inductor 742 are greater than or equal to 0.01 pH and less than or equal to 17.0 pH, respectively. In some embodiments, the inductance values of the second substrate via hole inductor 741 and the second substrate via hole inductor 742 are greater than or equal to 0.05 pH and less than or equal to 17.0 pH, respectively. In some embodiments, the inductance values of the second substrate via hole inductor 741 and the second substrate via hole inductor 742 are greater than or equal to 0.15 pH and less than or equal to 17.0 pH, respectively. In some embodiments, the inductance values of the second substrate via hole inductor 741 and the second substrate via hole inductor 742 are greater than or equal to 0.2 pH and less than or equal to 17.0 pH, respectively. In some embodiments, the inductance values of the second substrate via hole inductor 741 and the second substrate via hole inductor 742 are greater than or equal to 0.25 pH and less than or equal to 17.0 pH, respectively. In some embodiments, the inductance values of the second substrate via hole inductor 741 and the second substrate via hole inductor 742 are greater than or equal to 0.3 pH and less than or equal to 17.0 pH, respectively. In some embodiments, the inductance values of the second substrate via hole inductor 741 and the second substrate via hole inductor 742 are greater than or equal to 0.1 pH and less than or equal to 25.0 pH, respectively. In some embodiments, the inductance values of the second substrate via hole inductor 741 and the second substrate via hole inductor 742 are greater than or equal to 0.1 pH and less than or equal to 20.0 pH, respectively. In some embodiments, the inductance values of the second substrate via hole inductor 741 and the second substrate via hole inductor 742 are greater than or equal to 0.1 pH and less than or equal to 15.0 pH, respectively. In some embodiments, the inductance values of the second substrate via hole inductor 741 and the second substrate via hole inductor 742 are greater than or equal to 0.1 pH and less than or equal to 13.0 pH, respectively. In some embodiments, the inductance values of the second substrate via hole inductor 741 and the second substrate via hole inductor 742 are greater than or equal to 0.1 pH and less than or equal to 11.0 pH, respectively. In some embodiments, the inductance values of the second substrate via hole inductor 741 and the second substrate via hole inductor 742 are greater than or equal to 0.1 pH and less than or equal to 9.0 pH, respectively.

In some preferable embodiments, the thickness T of the semiconductor substrate 10 is greater than or equal to 10 μm and less than or equal to 40 μm. In some embodiments, the thickness T of the semiconductor substrate 10 is greater than or equal to 5 μm and less than or equal to 40 μm. In some embodiments, the thickness T of the semiconductor substrate 10 is greater than or equal to 8 μm and less than or equal to 40 μm. In some embodiments, the thickness T of the semiconductor substrate 10 is greater than or equal to 13 μm and less than or equal to 40 μm. In some embodiments, the thickness T of the semiconductor substrate 10 is greater than or equal to 15 μm and less than or equal to 40 μm. In some embodiments, the thickness T of the semiconductor substrate 10 is greater than or equal to 10 μm and less than or equal to 35 μm. In some embodiments, the thickness T of the semiconductor substrate 10 is greater than or equal to 10 μm and less than or equal to 30 μm. In some embodiments, the thickness T of the semiconductor substrate 10 is greater than or equal to 10 μm and less than or equal to 25 μm. In some embodiments, the thickness T of the semiconductor substrate 10 is greater than or equal to 10 μm and less than or equal to 20 μm. In some embodiments, the thickness T of the semiconductor substrate 10 is greater than or equal to 10 μm and less than or equal to 45 μm. In some embodiments, the thickness T of the semiconductor substrate 10 is greater than or equal to 10 μm and less than or equal to 50 μm.

In some embodiments, the thickness of the seed metal layer 20 is greater than or equal to 0.1 μm and less than or equal to 1 μm. In some embodiments, the thickness of the seed metal layer 20 is greater than or equal to 0.1 μm and less than or equal to 0.9 μm. In some embodiments, the thickness of the seed metal layer 20 is greater than or equal to 0.1 μm and less than or equal to 0.8 μm. In some embodiments, the thickness of the seed metal layer 20 is greater than or equal to 0.1 μm and less than or equal to 0.7 μm. In some embodiments, the thickness of the seed metal layer 20 is greater than or equal to 0.1 μm and less than or equal to 0.6 μm. In some embodiments, the thickness of the seed metal layer 20 is greater than or equal to 0.1 μm and less than or equal to 0.5 μm. In some embodiments, the thickness of the seed metal layer 20 is greater than or equal to 0.2 μm and less than or equal to 1 μm. In some embodiments, the thickness of the seed metal layer 20 is greater than or equal to 0.3 μm and less than or equal to 1 μm. In some embodiments, the thickness of the seed metal layer 20 is greater than or equal to 0.4 μm and less than or equal to 1 μm. In some embodiments, the thickness of the seed metal layer 20 is greater than or equal to 0.5 μm and less than or equal to 1 μm.

In some embodiments, the thickness of the backside metal layer 30 is greater than or equal to 1 μm and less than or equal to 10 μm. In some embodiments, the thickness of the backside metal layer 30 is greater than or equal to 1 μm and less than or equal to 9 μm. In some embodiments, the thickness of the backside metal layer 30 is greater than or equal to 1 μm and less than or equal to 8 μm. In some embodiments, the thickness of the backside metal layer 30 is greater than or equal to 1 μm and less than or equal to 7 μm. In some embodiments, the thickness of the backside metal layer 30 is greater than or equal to 1 μm and less than or equal to 6 μm. In some embodiments, the thickness of the backside metal layer 30 is greater than or equal to 1 μm and less than or equal to 5 μm. In some embodiments, the thickness of the backside metal layer 30 is greater than or equal to 2 μm and less than or equal to 10 μm. In some embodiments, the thickness of the backside metal layer 30 is greater than or equal to 3 μm and less than or equal to 10 μm. In some embodiments, the thickness of the backside metal layer 30 is greater than or equal to 4 μm and less than or equal to 10 μm. In some embodiments, the thickness of the backside metal layer 30 is greater than or equal to 5 μm and less than or equal to 10 μm.

As disclosed in the above description and attached drawings, the present invention can provide a semiconductor integrated circuit and a circuit layout method for semiconductor integrated circuit. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A semiconductor integrated circuit comprising:
a semiconductor substrate, wherein said semiconductor substrate has a first substrate via hole, a top surface and a bottom surface, said first substrate via hole has an inner surface, said inner surface of said first substrate via hole includes a bottom and a surrounding, said surrounding of said inner surface of said first substrate via hole is at least partially defined by said semiconductor substrate;
a first circuit layout, which comprises:
a front-side metal layer formed on said top surface of said semiconductor substrate, wherein said bottom of said inner surface of said first substrate via hole is at least partially defined by said front-side metal layer; and
a second circuit layout, which comprises:
a seed metal layer formed on said inner surface of said first substrate via hole and said bottom surface of said semiconductor substrate, wherein said seed metal layer has an outer surface; and
a backside metal layer formed on said outer surface of said seed metal layer;
wherein said first substrate via hole has an aspect ratio, said aspect ratio of said first substrate via hole is greater than or equal to 0.2 and less than or equal to 3, thereby a thickness uniformity of said backside metal layer is improved.

2. The semiconductor integrated circuit according to claim 1, wherein said seed metal layer includes a first-substrate-via-hole-bottom seed metal layer formed on said bottom of said inner surface of said first substrate via hole, a first-substrate-via-hole-surrounding seed metal layer formed on said surrounding of said inner surface of said first substrate via hole, and a first-substrate-bottom-surface seed metal layer formed on said bottom surface of said semiconductor substrate; wherein said outer surface of said seed metal layer includes an outer surface of said first-substrate-via-hole-bottom seed metal layer, an outer surface of said first-substrate-via-hole-surrounding seed metal layer, and an outer surface of said first-substrate-bottom-surface seed metal layer; wherein said backside metal layer includes a first-substrate-via-hole-bottom backside metal layer formed on said outer surface of said first-substrate-via-hole-bottom seed metal layer, a first-substrate-via-hole-surrounding backside metal layer formed on said outer surface of said first-substrate-via-hole-surrounding seed metal layer, and a first-substrate-bottom-surface backside metal layer formed on said outer surface of said first-substrate-bottom-surface seed metal layer; wherein said second circuit layout includes a first-substrate-via-hole-bottom connection part, a first substrate via hole inductor, and a first electrical connection part; said first-substrate-via-hole-bottom connection part includes said first-substrate-via-hole-bottom seed metal layer and said first-substrate-via-hole-bottom backside metal layer; said first substrate via hole inductor includes said first-substrate-via-hole-surrounding seed metal layer and said first-substrate-via-hole-surrounding backside metal layer; said first electrical connection part includes said first-substrate-bottom-surface seed metal layer and said first-substrate-bottom-surface backside metal layer; wherein said first substrate via hole inductor is a hot via inductor.

3. The semiconductor integrated circuit according to claim 2, wherein said semiconductor integrated circuit is electrically connected to an RF signal output terminal or an RF signal input terminal through said first electrical connection part.

4. The semiconductor integrated circuit according to claim 2, wherein said first substrate via hole inductor has a first inductance value, wherein said first inductance value of said first substrate via hole inductor is greater than or equal to 0.1 pH and less than or equal to 17.0 pH.

5. The semiconductor integrated circuit according to claim 1, wherein said first substrate via hole has a width, said width of said first substrate via hole is greater than or equal to 5 μm and less than or equal to 50 μm.

6. The semiconductor integrated circuit according to claim 1, wherein said first substrate via hole has a depth, said depth of said first substrate via hole is greater than or equal to 10 μm and less than or equal to 40 μm.

7. The semiconductor integrated circuit according to claim 1, wherein said front-side metal layer comprises a first part and a second part, said bottom of said inner surface of said first substrate via hole is at least partially defined by said first part of said front-side metal layer; said first-substrate-via-hole-bottom seed metal layer is electrically connected to said first part of said front-side metal layer; wherein said semiconductor substrate further includes a second substrate via hole, said second substrate via hole has an inner surface, said inner surface of said second substrate via hole includes a bottom and a surrounding, said surrounding of said inner surface of said second substrate via hole is at least partially defined by said semiconductor substrate, said bottom of said inner surface of said second substrate via hole is at least partially defined by said second part of said front-side metal layer; said bottom surface of said semiconductor substrate comprises a first area, a second area, and a separation area, said separation area separates said first area of said bottom surface of said semiconductor substrate from said second area of said bottom surface of said semiconductor substrate; wherein said seed metal layer is formed on said inner surface of said first substrate via hole, said inner surface of said second substrate via hole, said first area of said bottom surface of said semiconductor substrate, and said second area of said bottom surface of said semiconductor substrate; said first-substrate-bottom-surface seed metal layer is formed on said first area of said bottom surface of said semiconductor substrate; said seed metal layer further includes a second-substrate-via-hole-bottom seed metal layer formed on said bottom of said inner surface of said second substrate via hole, a second-substrate-via-hole-surrounding seed metal layer formed on said surrounding of said inner surface of said second substrate via hole, and a second-substrate-bottom-surface seed metal layer formed on said second area of said bottom surface of said semiconductor substrate; said second-substrate-via-hole-bottom seed metal layer is electrically connected to said second part of said front-side metal layer; wherein said outer surface of said seed metal layer further includes an outer surface of said second-substrate-via-hole-bottom seed metal layer, an outer surface of said second-substrate-via-hole-surrounding seed metal layer, and an outer surface of said second-substrate-bottom-surface seed metal layer; wherein said backside metal layer further includes a second-substrate-via-hole-bottom backside metal layer formed on said outer surface of said second-substrate-via-hole-bottom seed metal layer, a second-substrate-via-hole-surrounding backside metal layer formed on said outer surface of said second-substrate-via-hole-surrounding seed metal layer, and a second-substrate-bottom-surface backside metal layer formed on said outer surface of said second-substrate-bottom-surface seed metal layer; wherein said second circuit layout further includes a second-substrate-via-hole-bottom connection part, a second substrate via hole inductor, and a second electrical connection part; said second-substrate-via-hole-bottom connection part includes said second-substrate-via-hole-bottom seed metal layer and said second-substrate-via-hole-bottom backside metal layer; said second substrate via hole inductor includes said second-substrate-via-hole-surrounding seed metal layer and said second-substrate-via-hole-surrounding backside metal layer; said second electrical connection part includes said second-substrate-bottom-surface seed metal layer and said second-substrate-bottom-surface backside metal layer.

8. The semiconductor integrated circuit according to claim 7, wherein said second substrate via hole inductor is a hot via inductor.

9. The semiconductor integrated circuit according to claim 8, wherein said semiconductor integrated circuit is electrically connected to one of an RF signal output terminal and an RF signal input terminal through said first electrical connection part, and said semiconductor integrated circuit is electrically connected to the other of said RF signal output terminal and said RF signal input terminal through said second electrical connection part.

10. The semiconductor integrated circuit according to claim 7, wherein said second substrate via hole inductor is a non-hot via inductor, said semiconductor integrated circuit is grounded through said second electrical connection part.

11. The semiconductor integrated circuit according to claim 7, wherein said second substrate via hole has an aspect ratio, said aspect ratio of said second substrate via hole is greater than or equal to 0.2 and less than or equal to 3.

12. The semiconductor integrated circuit according to claim 7, wherein said second substrate via hole has a width, said width of said second substrate via hole is greater than or equal to 5 μm and less than or equal to 50 μm.

13. The semiconductor integrated circuit according to claim 7, wherein said second substrate via hole has a depth, said depth of said second substrate via hole is greater than or equal to 10 μm and less than or equal to 40 μm.

14. The semiconductor integrated circuit according to claim 7, wherein said second substrate via hole inductor has a second inductance value, wherein said second inductance value of said second substrate via hole inductor is greater than or equal to 0.1 pH and less than or equal to 17.0 pH.

15. The semiconductor integrated circuit according to claim 1, wherein said semiconductor integrated circuit is an RF circuit.

16. The semiconductor integrated circuit according to claim 1, wherein said semiconductor substrate has a thickness, said thickness of said semiconductor substrate is greater than or equal to 10 μm and less than or equal to 40 μm.

17. The semiconductor integrated circuit according to claim 1, wherein said seed metal layer has a thickness, said thickness of said seed metal layer is greater than or equal to 0.1 μm and less than or equal to 1 μm.

18. The semiconductor integrated circuit according to claim 1, wherein said backside metal layer has a thickness, said thickness of said backside metal layer is greater than or equal to 1 μm and less than or equal to 10 μm.

19. The semiconductor integrated circuit according to claim 1, wherein said seed metal layer is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy.

20. The semiconductor integrated circuit according to claim 1, wherein said backside metal layer is made by at least one material selected from the group consisting of: Au and Cu.

21. The semiconductor integrated circuit according to claim 1, wherein said semiconductor substrate is made by one material selected from the group consisting of: GaAs, InP, GaN, sapphire and SiC.

22. A semiconductor integrated circuit comprising:
a semiconductor substrate, wherein said semiconductor substrate has a first substrate via hole, a top surface and a bottom surface, said first substrate via hole has an inner surface, said inner surface of said first substrate via hole includes a bottom and a surrounding, said surrounding of said inner surface of said first substrate via hole is at least partially defined by said semiconductor substrate;
a first circuit layout, which comprises:
a front-side metal layer formed on said top surface of said semiconductor substrate, wherein said bottom of said inner surface of said first substrate via hole is at least partially defined by said front-side metal layer; and
a second circuit layout, which comprises:
a seed metal layer formed on said inner surface of said first substrate via hole and said bottom surface of said semiconductor substrate, wherein said seed metal layer has an outer surface; and
a backside metal layer formed on said outer surface of said seed metal layer;
wherein said first substrate via hole has a depth and a width, said depth of said first substrate via hole is greater than or equal to 10 μm and less than or equal to 40 μm, said width of said first substrate via hole is greater than or equal to 5 μm and less than or equal to 50 μm, thereby a thickness uniformity of said backside metal layer is improved.

23. The semiconductor integrated circuit according to claim 22, wherein said seed metal layer includes a first-substrate-via-hole-bottom seed metal layer formed on said bottom of said inner surface of said first substrate via hole, a first-substrate-via-hole-surrounding seed metal layer formed on said surrounding of said inner surface of said first substrate via hole, and a first-substrate-bottom-surface seed metal layer formed on said bottom surface of said semiconductor substrate; wherein said outer surface of said seed metal layer includes an outer surface of said first-substrate-via-hole-bottom seed metal layer, an outer surface of said first-substrate-via-hole-surrounding seed metal layer, and an outer surface of said first-substrate-bottom-surface seed metal layer; wherein said backside metal layer includes a first-substrate-via-hole-bottom backside metal layer formed on said outer surface of said first-substrate-via-hole-bottom seed metal layer, a first-substrate-via-hole-surrounding backside metal layer formed on said outer surface of said first-substrate-via-hole-surrounding seed metal layer, and a first-substrate-bottom-surface backside metal layer formed on said outer surface of said first-substrate-bottom-surface seed metal layer; wherein said second circuit layout includes a first-substrate-via-hole-bottom connection part, a first substrate via hole inductor, and a first electrical connection part; said first-substrate-via-hole-bottom connection part includes said first-substrate-via-hole-bottom seed metal layer and said first-substrate-via-hole-bottom backside metal layer; said first substrate via hole inductor includes said first-substrate-via-hole-surrounding seed metal layer and said first-substrate-via-hole-surrounding backside metal layer; said first electrical connection part includes said first-substrate-bottom-surface seed metal layer and said first-substrate-bottom-surface backside metal layer; wherein said first substrate via hole inductor is a hot via inductor.

24. The semiconductor integrated circuit according to claim 23, wherein said semiconductor integrated circuit is electrically connected to an RF signal output terminal or an RF signal input terminal through said first electrical connection part.

25. The semiconductor integrated circuit according to claim 23, wherein said first substrate via hole inductor has a first inductance value, wherein said first inductance value of said first substrate via hole inductor is greater than or equal to 0.1 pH and less than or equal to 17.0 pH.

26. The semiconductor integrated circuit according to claim 22, wherein said front-side metal layer comprises a first part and a second part, said bottom of said inner surface of said first substrate via hole is at least partially defined by said first part of said front-side metal layer; said first-substrate-via-hole-bottom seed metal layer is electrically connected to said first part of said front-side metal layer; wherein said semiconductor substrate further includes a second substrate via hole, said second substrate via hole has an inner surface, said inner surface of said second substrate via hole includes a bottom and a surrounding, said surrounding of said inner surface of said second substrate via hole is at least partially defined by said semiconductor substrate, said bottom of said inner surface of said second substrate via hole is at least partially defined by said second part of said front-side metal layer; said bottom surface of said semiconductor substrate comprises a first area, a second area, and a separation area, said separation area separates said first area of said bottom surface of said semiconductor substrate from said second area of said bottom surface of said semiconductor substrate; wherein said seed metal layer is formed on said inner surface of said first substrate via hole, said inner surface of said second substrate via hole, said first area of said bottom surface of said semiconductor substrate, and said second area of said bottom surface of said semiconductor substrate; said first-substrate-bottom-surface seed metal layer is formed on said first area of said bottom surface of said semiconductor substrate; said seed metal layer further includes a second-substrate-via-hole-bottom seed metal layer formed on said bottom of said inner surface of said second substrate via hole, a second-substrate-via-hole-surrounding seed metal layer formed on said surrounding of said inner surface of said second substrate via hole, and a second-substrate-bottom-surface seed metal layer formed on said second area of said bottom surface of said semiconductor substrate; said second-substrate-via-hole-bottom seed metal layer is electrically connected to said second part of said front-side metal layer; wherein said outer surface of said seed metal layer further includes an outer surface of said second-substrate-via-hole-bottom seed metal layer, an outer surface of said second-substrate-via-hole-surrounding seed metal layer, and an outer surface of said second-substrate-bottom-surface seed metal layer; wherein said backside metal layer further includes a second-substrate-via-hole-bottom backside metal layer formed on said outer surface of said second-substrate-via-hole-bottom seed metal layer, a second-substrate-via-hole-surrounding backside metal layer formed on said outer surface of said second-substrate-via-hole-surrounding seed metal layer, and a second-substrate-bottom-surface backside metal layer formed on said outer surface of said second-substrate-bottom-surface seed metal layer; wherein said second circuit layout further includes a second-substrate-via-hole-bottom connection part, a second substrate via hole inductor, and a second electrical connection part; said second-substrate-via-hole-bottom connection part includes said second-substrate-via-hole-bottom seed metal layer and said second-substrate-via-hole-bottom backside metal layer; said second substrate via hole inductor includes said second-substrate-via-hole-surrounding seed metal layer and said second-substrate-via-hole-surrounding backside metal layer; said second electrical connection part includes said second-substrate-bottom-surface seed metal layer and said second-substrate-bottom-surface backside metal layer.

27. The semiconductor integrated circuit according to claim 26, wherein said second substrate via hole inductor is a hot via inductor.

28. The semiconductor integrated circuit according to claim 27, wherein said semiconductor integrated circuit is electrically connected to one of an RF signal output terminal and an RF signal input terminal through said first electrical connection part, and said semiconductor integrated circuit is electrically connected to the other of said RF signal output terminal and said RF signal input terminal through said second electrical connection part.

29. The semiconductor integrated circuit according to claim 26, wherein said second substrate via hole inductor is a non-hot via inductor, said semiconductor integrated circuit is grounded through said second electrical connection part.

30. The semiconductor integrated circuit according to claim 26, wherein said second substrate via hole has an aspect ratio, said aspect ratio of said second substrate via hole is greater than or equal to 0.2 and less than or equal to 3.

31. The semiconductor integrated circuit according to claim 26, wherein said second substrate via hole has a width, said width of said second substrate via hole is greater than or equal to 5 μm and less than or equal to 50 μm.

32. The semiconductor integrated circuit according to claim 26, wherein said second substrate via hole has a depth, said depth of said second substrate via hole is greater than or equal to 10 μm and less than or equal to 40 μm.

33. The semiconductor integrated circuit according to claim 26, wherein said second substrate via hole inductor has a second inductance value, wherein said second inductance value of said second substrate via hole inductor is greater than or equal to 0.1 pH and less than or equal to 17.0 pH.

34. The semiconductor integrated circuit according to claim 22, wherein said semiconductor integrated circuit is an RF circuit.

35. The semiconductor integrated circuit according to claim 22, wherein said semiconductor substrate has a thickness, said thickness of said semiconductor substrate is greater than or equal to 10 μm and less than or equal to 40 μm.

36. The semiconductor integrated circuit according to claim 22, wherein said seed metal layer has a thickness, said thickness of said seed metal layer is greater than or equal to 0.1 μm and less than or equal to 1 μm.

37. The semiconductor integrated circuit according to claim 22, wherein said backside metal layer has a thickness, said thickness of said backside metal layer is greater than or equal to 1 μm and less than or equal to 10 μm.

38. The semiconductor integrated circuit according to claim 22, wherein said seed metal layer is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy.

39. The semiconductor integrated circuit according to claim 22, wherein said backside metal layer is made by at least one material selected from the group consisting of: Au and Cu.

40. The semiconductor integrated circuit according to claim 22, wherein said semiconductor substrate is made by one material selected from the group consisting of: GaAs, InP, GaN, sapphire and SiC.

41. A semiconductor integrated circuit comprising:
a semiconductor substrate, wherein said semiconductor substrate has a first substrate via hole, a top surface and a bottom surface, said first substrate via hole has an inner surface, said inner surface of said first substrate via hole includes a bottom and a surrounding, said surrounding of said inner surface of said first substrate via hole is at least partially defined by said semiconductor substrate;
a first circuit layout, which comprises:
a front-side metal layer formed on said top surface of said semiconductor substrate, wherein said bottom of said inner surface of said first substrate via hole is at least partially defined by said front-side metal layer; and
a second circuit layout, which comprises:
a seed metal layer formed on said inner surface of said first substrate via hole and said bottom surface of said semiconductor substrate, wherein said seed metal layer includes a first-substrate-via-hole-bottom seed metal layer formed on said bottom of said inner surface of said first substrate via hole, a first-substrate-via-hole-surrounding seed metal layer formed on said surrounding of said inner surface of said first substrate via hole, and a first-substrate-bottom-surface seed metal layer formed on said bottom surface of said semiconductor substrate; wherein said first-substrate-via-hole-bottom seed metal layer is electrically connected to said front-side metal layer; wherein said seed metal layer has an outer surface; wherein said outer surface of said seed metal layer includes an outer surface of said first-substrate-via-hole-bottom seed metal layer, an outer surface of said first-substrate-via-hole-surrounding seed metal layer, and an outer surface of said first-substrate-bottom-surface seed metal layer; and
a backside metal layer formed on said outer surface of said seed metal layer; wherein said backside metal layer includes a first-substrate-via-hole-bottom backside metal layer formed on said outer surface of said first-substrate-via-hole-bottom seed metal layer, a first-substrate-via-hole-surrounding backside metal layer formed on said outer surface of said first-substrate-via-hole-surrounding seed metal layer, and a first-substrate-bottom-surface backside metal layer formed on said outer surface of said first-substrate-bottom-surface seed metal layer;
wherein said second circuit layout includes a first-substrate-via-hole-bottom connection part, a first substrate via hole inductor, and a first electrical connection part; said first-substrate-via-hole-bottom connection part includes said first-substrate-via-hole-bottom seed metal layer and said first-substrate-via-hole-bottom backside metal layer; said first substrate via hole inductor includes said first-substrate-via-hole-surrounding seed metal layer and said first-substrate-via-hole-surrounding backside metal layer; said first electrical connection part includes said first-substrate-bottom-surface seed metal layer and said first-substrate-bottom-surface backside metal layer; wherein said first substrate via hole inductor is a hot via inductor.

42. The semiconductor integrated circuit according to claim 41, wherein said first substrate via hole has a width, said width of said first substrate via hole is greater than or equal to 5 μm and less than or equal to 50 μm.

43. The semiconductor integrated circuit according to claim 41, wherein said first substrate via hole has a depth, said depth of said first substrate via hole is greater than or equal to 10 μm and less than or equal to 40 μm.

44. The semiconductor integrated circuit according to claim 41, wherein said semiconductor integrated circuit is electrically connected to an RF signal output terminal or an RF signal input terminal through said first electrical connection part.

45. The semiconductor integrated circuit according to claim 41, wherein said first substrate via hole inductor has a first inductance value, wherein said first inductance value of said first substrate via hole inductor is greater than or equal to 0.1 pH and less than or equal to 17.0 pH.

46. The semiconductor integrated circuit according to claim 41, wherein said front-side metal layer comprises a first part and a second part, said bottom of said inner surface of said first substrate via hole is at least partially defined by said first part of said front-side metal layer; said first-substrate-via-hole-bottom seed metal layer is electrically connected to said first part of said front-side metal layer; wherein said semiconductor substrate further includes a second substrate via hole, said second substrate via hole has an inner surface, said inner surface of said second substrate via hole includes a bottom and a surrounding, said surrounding of said inner surface of said second substrate via hole is at least partially defined by said semiconductor substrate, said bottom of said inner surface of said second substrate via hole is at least partially defined by said second part of said front-side metal layer; said bottom surface of said semiconductor substrate comprises a first area, a second area, and a separation area, said separation area separates said first area of said bottom surface of said semiconductor substrate from said second area of said bottom surface of said semiconductor substrate; wherein said seed metal layer is formed on said inner surface of said first substrate via hole, said inner surface of said second substrate via hole, said first area of said bottom surface of said semiconductor substrate, and said second area of said bottom surface of said semiconductor substrate; said first-substrate-bottom-surface seed metal layer is formed on said first area of said bottom surface of said semiconductor substrate; said seed metal layer further includes a second-substrate-via-hole-bottom seed metal layer formed on said bottom of said inner surface of said second substrate via hole, a second-substrate-via-hole-surrounding seed metal layer formed on said surrounding of said inner surface of said second substrate via hole, and a second-substrate-bottom-surface seed metal layer formed on said second area of said bottom surface of said semiconductor substrate; said second-substrate-via-hole-bottom seed metal layer is electrically connected to said second part of said front-side metal layer; wherein said outer surface of said seed metal layer further includes an outer surface of said second-substrate-via-hole-bottom seed metal layer, an outer surface of said second-substrate-via-hole-surrounding seed metal layer, and an outer surface of said second-substrate-bottom-surface seed metal layer; wherein said backside metal layer further includes a second-substrate-via-hole-bottom backside metal layer formed on said outer surface of said second-substrate-via-hole-bottom seed metal layer, a second-substrate-via-hole-surrounding backside metal layer formed on said outer surface of said second-substrate-via-hole-surrounding seed metal layer, and a second-substrate-bottom-surface backside metal layer formed on said outer surface of said second-substrate-bottom-surface seed metal layer; wherein said second circuit layout further includes a second-substrate-via-hole-bottom connection part, a second substrate via hole inductor, and a second electrical connection part; said second-substrate-via-hole-bottom connection part includes said second-substrate-via-hole-bottom seed metal layer and said second-substrate-via-hole-bottom backside metal layer; said second substrate via hole inductor includes said second-substrate-via-hole-surrounding seed metal layer and said second-substrate-via-hole-surrounding backside metal layer; said second electrical connection part includes said second-substrate-bottom-surface seed metal layer and said second-substrate-bottom-surface backside metal layer.

47. The semiconductor integrated circuit according to claim 46, wherein said second substrate via hole inductor is a hot via inductor.

48. The semiconductor integrated circuit according to claim 47, wherein said semiconductor integrated circuit is electrically connected to one of an RF signal output terminal and an RF signal input terminal through said first electrical connection part, and said semiconductor integrated circuit is electrically connected to the other of said RF signal output terminal and said RF signal input terminal through said second electrical connection part.

49. The semiconductor integrated circuit according to claim 46, wherein said second substrate via hole inductor is a non-hot via inductor, said semiconductor integrated circuit is grounded through said second electrical connection part.

50. The semiconductor integrated circuit according to claim 46, wherein said second substrate via hole has an aspect ratio, said aspect ratio of said second substrate via hole is greater than or equal to 0.2 and less than or equal to 3.

51. The semiconductor integrated circuit according to claim 46, wherein said second substrate via hole has a width, said width of said second substrate via hole is greater than or equal to 5 μm and less than or equal to 50 μm.

52. The semiconductor integrated circuit according to claim 46, wherein said second substrate via hole has a depth, said depth of said second substrate via hole is greater than or equal to 10 μm and less than or equal to 40 μm.

53. The semiconductor integrated circuit according to claim 46, wherein said second substrate via hole inductor has a second inductance value, wherein said second inductance value of said second substrate via hole inductor is greater than or equal to 0.1 pH and less than or equal to 17.0 pH.

54. The semiconductor integrated circuit according to claim 41, wherein said semiconductor integrated circuit is an RF circuit.

55. The semiconductor integrated circuit according to claim 41, wherein said semiconductor substrate has a thickness, said thickness of said semiconductor substrate is greater than or equal to 10 μm and less than or equal to 40 μm.

56. The semiconductor integrated circuit according to claim 41, wherein said seed metal layer has a thickness, said thickness of said seed metal layer is greater than or equal to 0.1 μm and less than or equal to 1 μm.

57. The semiconductor integrated circuit according to claim 41, wherein said backside metal layer has a thickness, said thickness of said backside metal layer is greater than or equal to 1 μm and less than or equal to 10 μm.

58. The semiconductor integrated circuit according to claim 41, wherein said seed metal layer is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy.

59. The semiconductor integrated circuit according to claim 41, wherein said backside metal layer is made by at least one material selected from the group consisting of: Au and Cu.

60. The semiconductor integrated circuit according to claim 41, wherein said semiconductor substrate is made by one material selected from the group consisting of: GaAs, InP, GaN, sapphire and SiC.

61. A circuit layout method for semiconductor integrated circuit comprising following steps of:
Step A0: designing a first-substrate-via-hole shape, a first-substrate-via-hole depth and a first-substrate-via-hole width of a first substrate via hole, a seed-metal-layer thickness of a seed metal layer, and a backside-metal-layer thickness of a backside metal layer such that a first substrate via hole inductor has a first inductance value;
Step A1: forming a first circuit layout on a top surface of a semiconductor substrate, wherein said first circuit layout comprises a front-side metal layer;
Step B1: etching said semiconductor substrate to form said first substrate via hole such that said first substrate via hole has said first-substrate-via-hole shape, said first-substrate-via-hole depth, and said first-substrate-via-hole width, wherein said first substrate via hole has an inner surface, said inner surface of said first substrate via hole includes a bottom and a surrounding, wherein said bottom of said inner surface of said first substrate via hole is at least partially defined by said front-side metal layer, said surrounding of said inner surface of said first substrate via hole is at least partially defined by said semiconductor substrate; and
Step C1: forming a second circuit layout, which comprises following steps of:
Step C10: forming said seed metal layer on said inner surface of said first substrate via hole and a bottom surface of said semiconductor substrate such that said seed metal layer has said seed-metal-layer thickness, wherein said seed metal layer includes a first-substrate-via-hole-bottom seed metal layer formed on said bottom of said inner surface of said first substrate via hole, a first-substrate-via-hole-surrounding seed metal layer formed on said surrounding of said inner surface of said first substrate via hole, and a first-substrate-bottom-surface seed metal layer formed on said bottom surface of said semiconductor substrate; wherein said first-substrate-via-hole-bottom seed metal layer is electrically connected to said front-side metal layer; wherein said seed metal layer has an outer surface; wherein said outer surface of said seed metal layer includes an outer surface of said first-substrate-via-hole-bottom seed metal layer, an outer surface of said first-substrate-via-hole-surrounding seed metal layer, and an outer surface of said first-substrate-bottom-surface seed metal layer; and
Step C11: forming said backside metal layer on said outer surface of said seed metal layer such that said backside metal layer has said backside-metal-layer thickness, wherein said backside metal layer includes a first-substrate-via-hole-bottom backside metal layer formed on said outer surface of said first-substrate-via-hole-bottom seed metal layer, a first-substrate-via-hole-surrounding backside metal layer formed on said outer surface of said first-substrate-via-hole-surrounding seed metal layer, and a first-substrate-bottom-surface backside metal layer formed on said outer surface of said first-substrate-bottom-surface seed metal layer;
wherein said second circuit layout includes a first-substrate-via-hole-bottom connection part, a first substrate via hole inductor, and a first electrical connection part; said first-substrate-via-hole-bottom connection part includes said first-substrate-via-hole-bottom seed metal layer and said first-substrate-via-hole-bottom backside metal layer; said first substrate via hole inductor includes said first-substrate-via-hole-surrounding seed metal layer and said first-substrate-via-hole-surrounding backside metal layer; said first electrical connection part includes said first-substrate-bottom-surface seed metal layer and said first-substrate-bottom-surface backside metal layer.

62. The circuit layout method for semiconductor integrated circuit according to claim 61, wherein said first substrate via hole has an aspect ratio, said aspect ratio of said first substrate via hole is greater than or equal to 0.2 and less than or equal to 3.

63. The circuit layout method for semiconductor integrated circuit according to claim 61, wherein said first-substrate-via-hole width is greater than or equal to 5 μm and less than or equal to 50 μm.

64. The circuit layout method for semiconductor integrated circuit according to claim 61, wherein said first-substrate-via-hole depth is greater than or equal to 10 μm and less than or equal to 40 μm.

65. The circuit layout method for semiconductor integrated circuit according to claim 61, wherein said first inductance value of said first substrate via hole inductor is greater than or equal to 0.1 pH and less than or equal to 17.0 pH.

66. The circuit layout method for semiconductor integrated circuit according to claim 61, wherein said first substrate via hole inductor is a hot via inductor.

67. The circuit layout method for semiconductor integrated circuit according to claim 66, wherein said semiconductor integrated circuit is electrically connected to an RF signal output terminal or an RF signal input terminal through said first electrical connection part.

68. The circuit layout method for semiconductor integrated circuit according to claim 61, wherein said first substrate via hole inductor is a non-hot via inductor, said semiconductor integrated circuit is grounded through said first electrical connection part.

69. The circuit layout method for semiconductor integrated circuit according to claim 61, wherein said front-side metal layer comprises a first part and a second part, said bottom of said inner surface of said first substrate via hole is at least partially defined by said first part of said front-side metal layer; said first-substrate-via-hole-bottom seed metal layer is electrically connected to said first part of said front-side metal layer; wherein said Step A10 further comprises a following step of: designing a second-substrate-via-hole shape, a second-substrate-via-hole depth and a second-substrate-via-hole width of a second substrate via hole such that a second substrate via hole inductor has a second inductance value; wherein said Step B1 further comprises a following step of: etching said semiconductor substrate to form said second substrate via hole such that said second substrate via hole has said second-substrate-via-hole shape, said second-substrate-via-hole depth, and said second-substrate-via-hole width, wherein said second substrate via hole has an inner surface, said inner surface of said second substrate via hole includes a bottom and a surrounding, wherein said bottom of said inner surface of said second substrate via hole is at least partially defined by said second part of said front-side metal layer, said surrounding of said inner surface of said second substrate via hole is at least partially defined by said semiconductor substrate; wherein said bottom surface of said semiconductor substrate comprises a first area, a second area, and a separation area, said separation area separates said first area of said bottom surface of said semiconductor substrate from said second area of said bottom surface of said semiconductor substrate; wherein said seed metal layer is formed on said inner surface of said first substrate via hole, said inner surface of said second substrate via hole, said first area of said bottom surface of said semiconductor substrate, and said second area of said bottom surface of said semiconductor substrate; said first-substrate-bottom-surface seed metal layer is formed on said first area of said bottom surface of said semiconductor substrate; said seed metal layer further includes a second-substrate-via-hole-bottom seed metal layer formed on said bottom of said inner surface of said second substrate via hole, a second-substrate-via-hole-surrounding seed metal layer formed on said surrounding of said inner surface of said second substrate via hole, and a second-substrate-bottom-surface seed metal layer formed on said second area of said bottom surface of said semiconductor substrate; said second-substrate-via-hole-bottom seed metal layer is electrically connected to said second part of said front-side metal layer; wherein said outer surface of said seed metal layer further includes an outer surface of said second-substrate-via-hole-bottom seed metal layer, an outer surface of said second-substrate-via-hole-surrounding seed metal layer, and an outer surface of said second-substrate-bottom-surface seed metal layer; wherein said backside metal layer is formed on said outer surface of said first-substrate-via-hole-bottom seed metal layer, said outer surface of said first-substrate-via-hole-surrounding seed metal layer, said outer surface of said first-substrate-bottom-surface seed metal layer, said outer surface of said second-substrate-via-hole-bottom seed metal layer, said outer surface of said second-substrate-via-hole-surrounding seed metal layer, and said outer surface of said second-substrate-bottom-surface seed metal layer; wherein said backside metal layer further includes a second-substrate-via-hole-bottom backside metal layer formed on said outer surface of said second-substrate-via-hole-bottom seed metal layer, a second-substrate-via-hole-surrounding backside metal layer formed on said outer surface of said second-substrate-via-hole-surrounding seed metal layer, and a second-substrate-bottom-surface backside metal layer formed on said outer surface of said second-substrate-bottom-surface seed metal layer; wherein said second circuit layout further includes a second-substrate-via-hole-bottom connection part, a second substrate via hole inductor, and a second electrical connection part; said second-substrate-via-hole-bottom connection part includes said second-substrate-via-hole-bottom seed metal layer and said second-substrate-via-hole-bottom backside metal layer; said second substrate via hole inductor includes said second-substrate-via-hole-surrounding seed metal layer and said second-substrate-via-hole-surrounding backside metal layer; said second electrical connection part includes said second-substrate-bottom-surface seed metal layer and said second-substrate-bottom-surface backside metal layer.

70. The circuit layout method for semiconductor integrated circuit according to claim 69, wherein said second substrate via hole has an aspect ratio, said aspect ratio of said second substrate via hole is greater than or equal to 0.2 and less than or equal to 3.

71. The circuit layout method for semiconductor integrated circuit according to claim 69, wherein said second-substrate-via-hole width is greater than or equal to 5 μm and less than or equal to 50 μm.

72. The circuit layout method for semiconductor integrated circuit according to claim 69, wherein said second-substrate-via-hole depth is greater than or equal to 10 μm and less than or equal to 40 μm.

73. The circuit layout method for semiconductor integrated circuit according to claim 69, wherein said second inductance value of said second substrate via hole inductor is greater than or equal to 0.1 pH and less than or equal to 17.0 pH.

74. The circuit layout method for semiconductor integrated circuit according to claim 69, wherein said second substrate via hole inductor is a hot via inductor.

75. The circuit layout method for semiconductor integrated circuit according to claim 74, wherein said semiconductor integrated circuit is electrically connected to one of an RF signal output terminal and an RF signal input terminal through said second electrical connection part.

76. The circuit layout method for semiconductor integrated circuit according to claim 69, wherein said first substrate via hole inductor and said second substrate via hole inductor are respectively a hot via inductor.

77. The circuit layout method for semiconductor integrated circuit according to claim 76, wherein said semiconductor integrated circuit is electrically connected to one of an RF signal output terminal and an RF signal input terminal through said first electrical connection part, and said semiconductor integrated circuit is electrically connected to the other of said RF signal output terminal and said RF signal input terminal through said second electrical connection part.

78. The circuit layout method for semiconductor integrated circuit according to claim 69, wherein said second substrate via hole inductor is a non-hot via inductor, said semiconductor integrated circuit is grounded through said second electrical connection part.

79. The circuit layout method for semiconductor integrated circuit according to claim 61, wherein said semiconductor integrated circuit is an RF circuit.

80. The circuit layout method for semiconductor integrated circuit according to claim 61, wherein after said Step A1 and before said Step B1, said circuit layout method further comprises a following step of: thinning said semiconductor substrate such that said semiconductor substrate has a thickness greater than or equal to 10 μm and less than or equal to 40 μm.

81. The circuit layout method for semiconductor integrated circuit according to claim 61, wherein said seed-metal-layer thickness of said seed metal layer is greater than or equal to 0.1 μm and less than or equal to 1 μm.

82. The circuit layout method for semiconductor integrated circuit according to claim 61, wherein said backside-metal-layer thickness of said backside metal layer is greater than or equal to 1 μm and less than or equal to 10 μm.

83. The circuit layout method for semiconductor integrated circuit according to claim 61, wherein said seed metal layer is made by at least one material selected from the group consisting of: Pd, Pd alloy, Au, Au alloy, Ni, Ni alloy, Co, Co alloy, Cr, Cr alloy, Cu, Cu alloy, Pt, Pt alloy, Sn, Sn alloy, Rh and Rh alloy.

84. The circuit layout method for semiconductor integrated circuit according to claim 61, wherein said backside metal layer is made by at least one material selected from the group consisting of: Au and Cu.

85. The circuit layout method for semiconductor integrated circuit according to claim 61, wherein said semiconductor substrate is made by one material selected from the group consisting of: GaAs, InP, GaN, sapphire and SiC.
